(19) United States
(12) Patent Application Publication
(10) Pub. No.: US 2023/0153676 A1
(43) Pub. Date: May 18, 2023

(54) CHEMICALLY TUNABLE OPTICALLY ADDRESSABLE MOLECULR-SPIN QUBIT AND ASSOCIATED METHODS

(71) Applicants: The University of Chicago, Chicago, IL (US); Northwestern University, Evanston, IL (US)

(72) Inventors: Danna E. Freedman, Evanston, IL (US); David D. Awschalom, Chicago, IL (US); Dan W. Laorenza, Evanston, IL (US); Majed S. Fataftah, New Haven, CT (US); Sam L. Bayliss, Chicago, IL (US); Berk Diler, Chicago, IL (US); Peter J. Mintun, Chicago, IL (US)

(21) Appl. No.: 17/995,825

(22) PCT Filed: Apr. 9, 2021
(86) PCT No.: PCT/US2021/026728

§ 371 Date: Oct. 7, 2022

Related U.S. Application Data
(60) Provisional application No. 63/008,589, filed on Apr. 10, 2020.

(51) Int. Cl. G06N 10/40; C07F 11/00; C07F 7/22

(52) U.S. Cl. CPC G06N 10/40; C07F 11/00; C07F 7/2208; C07B 2200/13

(57) ABSTRACT

A molecular-spin qubit is formed from a coordination complex having a plurality of strong-field ligands bound to a metal-atom center. The ground state has non-zero spin, and the resulting ground-state magnetic sublevels are separated by microwave or millimeter-wave frequencies, even in the absence of an external field. Two of these sublevels may be used as a quantum resource for quantum information processing, quantum communication, quantum memory, sensing, and other applications. Optical pumping to an excited state may be used to spin-polarize the molecular-spin qubit, and to measure its population by detecting photoluminescence. The energy-level structure of the metal-atom center can be modified due to its interaction with the ligands, therefore allowing the molecular-spin qubit to be “chemically tuned” based on the number and type of ligands. Ensembles of these molecular-spin qubits can be controllably deposited on a surface, or otherwise integrated into devices and structures.

### RELATED APPLICATIONS

This application claims priority to U.S. Provisional Patent Application No. 63/008,589, filed Apr. 10, 2020, the entirety of which is incorporated herein by reference.

### STATEMENT REGARDING FEDERALLY SPONSORED RESEARCH OR DEVELOPMENT

This invention was made with government support under grant number N00014-17-1-3026 awarded by the Office of Naval Research, grant number D18AC00015KK1932 awarded by the Defense Advanced Research Projects Agency, grant number CHE-1455017 awarded by the National Science Foundation, and grant number DE-SC0019356 awarded by the Department of Energy. The government has certain rights in the invention.

### BACKGROUND

Various types of quantum-mechanical systems are used as quantum resources (e.g., quantum bits or “qubits”) for quantum information processing, quantum computing, quantum communication and error correction, quantum sensing, and other applications. Some of these quantum-mechanical systems have non-zero spin, in which case two non-degenerate ground-state magnetic sublevels may be selected to implement a qubit. Examples of such spin-bearing qubits include atoms, nuclei, ions, and solid-state defects.

### SUMMARY

Spin-bearing molecules are promising building blocks for quantum technologies as they can be chemically tuned, assembled into scalable arrays, and readily incorporated into diverse device architectures. In molecular systems, optically addressing ground-state spins can enable a wide range of applications in quantum information science, as has been demonstrated for solid-state defects. However, this important functionality has remained elusive for molecules.

The present embodiments feature series of synthesized organometallic, chromium (IV) molecules that can be optically addressed. These compounds display a ground-state spin that can be initialized and read out using light, and coherently manipulated with microwaves or millimeter waves. In addition, through atomistic modification of the molecular structure, it is possible to tune the spin and optical properties of these compounds, paving the way for designer quantum systems synthesized from the bottom-up.

The present embodiments feature coordination complexes that may be advantageously used as qubits (i.e., quantum bits), qutrits, and other types of quantum resources. These embodiments include methods for preparing and utilizing coordination complexes for quantum computation and information processing, quantum communication and teleportation, quantum memories, sensing, and other quantum-mechanical applications. Accordingly, the coordination complexes may also be referred to as “molecular-spin qubits”. For example, some of the methods presented herein can be used to initialize a coordination complex via spin polarizing. Other methods can be used to coherently control a spin-polarized coordination complex to deterministically place the coordination complex in a quantum superposition state. At the end of a quantum computation or sensing sequence, additional methods presented herein can be used to determine the spin population of the coordination complex by measuring photoluminescence (e.g., resonance phosphorescence) emitted by the coordination complex during optical pumping.

One aspect of the present embodiments is that the energy-level structure of an atom can be modified in numerous ways due to its interaction with ligands, therefore allowing the energy-level structure to be “chemically tuned” by selecting the type of ligands. This ability to chemically tune atomic structure advantageously gives rise to a significantly greater variety of energy-level structures as compared to that of the “bare” atom. Such variety increases the likelihood of finding energy-level structures that are particularly useful for implementing the present embodiments with existing technologies. For example, some of the modified energy-level structures may have transitions that coincide with readily-available lasers and microwave sources.

Another aspect of the present embodiments is that fabricating coordination complexes is experimentally simpler and faster than embedding atoms as defects in a crystal lattice. Thus, the present embodiments provide many of the advantages of using lattice defects as quantum resources, but with the added benefits of easier and more controllable fabrication and avoiding the stochastic nature of embedding atoms in a host lattice. Plus, the coordination complexes described herein may be utilized either with or without a host material, and there exists the possibility to chemically functionalize compounds with existing chemistry platforms.

In embodiments, a system for quantum-information processing includes a plurality of molecular-spin qubits, each of the molecular-spin qubits includes a plurality of strong-field ligands bound to a metal-atom center such that the metal-atom center has a ground state with non-zero spin and an excited state. Each of the molecular-spin qubits has an optical transition between the ground state and the excited state, the optical transition lying in the optical or infrared regions of the electromagnetic spectrum. Each of the molecular-spin qubits also has a spin transition between first and second sublevels of the ground state, the spin transition lying in the microwave or millimeter-wave region of the electromagnetic spectrum. A spin-selective optical process may be used to initialize and read out the ground-state spin of the molecular-spin quibts.

### BRIEF DESCRIPTION OF THE FIGURES

FIG. 1 shows of a coordination complex formed from a plurality of ligands bonded to a metal-atom center, in embodiments.

FIG. 2 is an energy-level diagram of the coordination complex of FIG. 1 for the example of Cr(o-tolyl)₄, in an embodiment.

FIG. 3 illustrates a method for spin polarizing the coordination complex of FIG. 1, in embodiments.

FIG. 4 illustrates a method for spin polarizing the coordination complex of FIG. 1 into a first ground-state magnetic sublevel, in embodiments.

FIG. 5 shows a coordination complex that is similar to the coordination complex of FIG. 1 except that an additional methyl group has been added to each of the ligands at the 3-position of the corresponding carbon ring, in an embodiment.

FIG. 6 shows a coordination complex that is similar to the coordination complex of FIG. 5, except that the additional methyl group 502 has been added to each of the ligands at the 4-position of the corresponding carbon ring, in an embodiment.

FIG. 7 shows a dilute crystal formed by diluting a plurality of the coordination complex of FIG. 1 within a host, in an embodiment.

FIG. 8A shows an energy-level diagram of Cr⁴⁺ depicting photoluminescence (PL) from the S=0 state.

FIG. 8B shows molecular structures for compounds 1, 2, and 3 determined by single-crystal X-ray diffraction. Hydrogen atoms are omitted for clarity. Ligand modifications for compounds 2 and 3 are highlighted.

FIG. 8C is an experimental schematic depicting optical excitation and PL collection for spin initialization and readout. Each Cr⁴⁺ compound is diluted in a single crystal of the isostructural S=0 tin (Sn) analogue. An illustrative structure of this single crystal is shown. A microwave field (B₁) from a waveguide is used for spin manipulation, and a static field (B₀) enables Zeeman splitting.

FIG. 8D shows PL spectra for the compounds 1-3 at 4 K using off-resonant (785 nm) excitation.

FIG. 8E shows Zeeman splitting of the zero-phonon line of the compound 1 at 9 T.

FIG. 8F shows optical lifetimes for the compounds 1-3 measured using resonant excitation at the zero-phonon line.

FIG. 8G shows X-band continuous-wave electron spin resonance (cwESR) spectra for the compounds 1-3 collected at 77 K. Simulations are shown as solid black lines, along with extracted D and E parameters.

FIG. 9A shows an energy-level structure illustrating optical spin initialization through spin-selective excitation.

FIG. 9B shows a photoluminescence excitation (PLE) spectrum obtained by sweeping a narrow-line laser over the zero-phonon line. The dashed line shows the excitation wavelength. The inset shows dependence of the PL on laser polarization, defined by the angle 0 from the crystal long axis.

FIG. 9C illustrates phonon sidebands under resonant and off-resonant excitation, showing emission line narrowing. The inset shows a schematic of subensemble excitation.

FIG. 9D illustrates time-resolved optical spin initialization.

FIG. 9E shows an all-optical measurement of the spin-lattice relaxation time (T₁).

FIG. 10A shows ODMR as a function of magnetic field and microwave frequency using continuous-wave optical excitation. Dashed lines are a simulation with the stated values of g and D.

FIG. 10B illustrates pulsed ODMR.

FIG. 10C illustrates Hahn-echo sequences.

FIG. 10D shows a measurement of Rabi oscillations between the |0 [symbol] and |−1 [symbol] spin sublevels (B₀=10 mT). The inset shows the microwave-power dependence of the Rabi oscillation frequency.

FIG. 10E is a pulsed ODMR spectrum (B₀=10 mT) and double Lorentzian fit (solid black line).

FIG. 10F shows a measurement of optically detected ground-state spin coherence (B₀=2 mT) with an exponential fit (solid black line).

FIG. 11A shows a cw-ODMR spectrum and simulation (solid black line) for the compound 1, with microwave transitions and ligand modifications depicted.

FIG. 11B shows a cw-ODMR spectrum and simulation (solid black line) for the compound 2, with microwave transitions and ligand modifications depicted.

FIG. 11C shows a cw-ODMR spectrum and simulation (solid black line) for the compound 3, with microwave transitions and ligand modifications depicted.

FIG. 12A is a standard d-orbital splitting diagram for ideal T_{d} symmetry.

FIG. 12B is a simplified energy level diagram for d² ions in a strong, tetrahedral ligand field. The compounds 1-3 all exhibit a descent in symmetry from ideal T_{d} symmetry both in solution (see FIG. 13) and the solid state, resulting in symmetry breaking of orbitally degenerate, multi-electron states.

FIG. 13A shows solution (Et₂O for 1-Cr and 2-Cr, Tol for 3-Cr) electronic absorption spectra for 1-Cr, 2-Cr, and 3-Cr at room temperature. As predicted from the crystal structure and zero-field splitting, each compound exhibits a descent in symmetry from ideal T_{d} resulting in >2 electronic transitions. Similar behavior is observed in other homoleptic, pseudo-tetrahedral Cr⁴⁺ and V³⁺ complexes, where the complexes exhibit C₂ᵥ symmetry in solution.

FIG. 13B shows solid-state (KBr for 1-Cr, 2-Cr and 3-Cr) electronic absorption spectra for 1-Cr, 2-Cr, and 3-Cr at room temperature.

FIG. 14A shows infrared spectroscopic data for 1-Cr, 2-Cr and 3-Cr.

FIG. 14B shows infrared spectroscopic data for 1-Sn, 2-Sn and 3-Sn.

FIG. 15A shows ¹H NMR of the compound 2 in CDCl₃ at room temperature with solvent impurity peaks labeled.

FIG. 15B shows ¹³C NMR of the compound 2 in CDCl₃ at room temperature with solvent impurity peaks labeled.

FIG. 16A is a schematic for optical and microwave experiments, in an embodiment.

FIG. 16B is a schematic for high magnetic field experiments, in an embodiment. Shortpass filter (SPF), longpass filter (LPF), dichroic beamsplitter (DBS), and Physical Property Measurement System (PPMS) are indicated.

FIG. 17 shows an X-band cw-ESR spectra for the compounds 1-3 at 77 K with simulations shown as solid black lines.

FIG. 18 shows experimental (left) and simulated (right) differential photo luminescence spectra as a function of magnetic field, along with measured and simulated zero-field PL spectrum for comparison. The feature around 1030 nm in the experimental data is part of the phonon sideband and is not included in the model.

FIG. 19 illustrates hole-burning dynamics used to extract the spin-selective pumping rates g₀ and g₁.

FIG. 20 shows power-dependent Rabi oscillation data for the compound 1 along with corresponding fast Fourier transforms (FFTs), taken at the |0 [symbol] <->|−1 [symbol] transition (B₀=10 mT). We calibrate the relative powers using a Schottky diode and use these along with the peaks from the FFTs to plot the Rabi frequency power dependence in the inset of FIG. 10D.

FIG. 21A shows a pulse sequence for echo-detected field-swept (EDFS) experiments.

FIG. 21B shows X-band EDFS spectra of the compounds 1-3 at 5 K with simulations (solid black lines) and corresponding parameters.

FIG. 22 is a table of cw-ESR simulation parameters for FIGS. 8G and 17.

FIG. 23 is magnetostructural analysis of the compounds 1-3.

FIG. 24 is a table of extracted T₁ and T₂ times from pulsed ESR measurements of a micro-crystalline powder of the compound 1 (see FIG. 21B). Errors are indicated in parentheses. For closest comparison to the pulsed ODMR measurements, pulsed ESR measurements were performed at 466 mT where the magnetic field is approximately parallel to the principal axis of the zero-field splitting tensor.

FIG. 25 is a table of crystallographic data for the structure refinement of 1-Cr, 2-Cr, and 3-Cr, measured at 100 K. We note that 1-Cr exhibits an expanded unit cell compared to 1 (see FIG. 27) which may result from steric hinderance around the smaller Cr⁴⁺ metal center due to the ortho methyl groups. A similar steric effect is posited to lower the crystal packing symmetry for Ge(o-tolyl)₄

FIG. 26 is a table of crystallographic data for the structure refinement of 2-Sn, measured at 100 K.

FIG. 27 is a table of crystallographic data for the structure refinement of the compound 1, 2, and 3, measured at 100 K.

FIG. 28A illustrates a method for off-resonant optical pumping of the coordination complex of FIGS. 1 and 2, in embodiments.

FIG. 28B shows how the method of FIG. 28A may be used with a coordination complex that is similar to the coordination complex of FIGS. 1 and 2, in an embodiment.

FIG. 29A illustrates a method for off-resonant optical pumping of the coordination complex of FIGS. 1 and 2 that is based on spin-selective excitation, in embodiments.

FIG. 29B shows how the method of FIG. 29A may be used with the coordination complex of FIG. 28B, in an embodiment.

FIG. 30A illustrates a method for off-resonant optical pumping of the coordination complex of FIGS. 1 and 2 that is based on an intersystem crossing, in embodiments.

FIG. 30B shows how the method of FIG. 30A may be used with the coordination complex of FIGS. 28B and 29B, in an embodiment.

### DETAILED DESCRIPTION

### Definitions

As used herein, the term “alkyl,” means a straight or branched chain hydrocarbon having the number of carbon atoms designated (i.e., C₁-C₆ alkyl means an alkyl having one to six carbon atoms) and includes straight and branched chains. Examples include methyl, ethyl, propyl, isopropyl, butyl, isobutyl, tert butyl, pentyl, neopentyl, and hexyl.

As used herein, the term “deuterated alkyl” refers to an alkyl group as defined herein wherein at least one hydrogen atom has been replaced with a deuterium atom. As such, deuterated alkyl groups of the disclosure may be partially deuterated or fully deuterated.

As used herein, the term “alkoxy” refers to the group —O-alkyl, wherein alkyl is as defined herein. Alkoxy includes, by way of example, methoxy, ethoxy, n-propoxy, isopropoxy, n-butoxy, sec-butoxy, t-butoxy and the like

As used herein, the term “haloalkyl” refers to an alkyl group, as defined above, substituted with one or more halo substituents, wherein alkyl and halo are as defined herein. Haloalkyl includes, by way of example, chloromethyl, trifluoromethyl, bromoethyl, chlorofluoroethyl, and the like.

As used herein, the term “aromatic” refers to a carbocycle or heterocycle with one or more polyunsaturated rings and having aromatic character, i.e., having (4n+2) delocalized π (pi) electrons, where n is an integer.

As used herein, the term “aryl” means an aromatic carbocyclic system. The term “aryl” includes, but is not limited to, phenyl, naphthyl, indanyl, and 1,2,3,4-tetrahydronaphthalenyl. In one embodiment, “aryl” means phenyl. In some embodiments, aryl groups have 6 carbon atoms. In some embodiments, aryl groups have from six to ten carbon atoms. In some embodiments, aryl groups have from six to sixteen carbon atoms.

As used herein, the term “deuterated aryl” refers to an aryl group as defined herein wherein at least one hydrogen atom has been replaced with a deuterium atom. As such, deuterated aryl groups of the disclosure may be partially deuterated or fully deuterated.

As used herein, the term “heteroaryl” means an aromatic carbocyclic system containing 1, 2, 3, or 4 heteroatoms selected independently from N, O, and S. The term “heteroaryl” includes, but is not limited to, furanyl, thienyl, oxazolyl, thiazolyl, imidazolyl, pyrazolyl, triazolyl, tetrazolyl, isoxazolyl, isothiazolyl, oxadiazolyl, thiadiazolyl, pyridinyl, pyridazinyl, pyrimidinyl, pyrazinyl.

As used herein, the term “deuterated heteroaryl” refers to a heteroaryl group as defined herein wherein at least one hydrogen atom has been replaced with a deuterium atom. As such, deuterated heteroaryl groups of the disclosure may be partially deuterated or fully deuterated.

As used herein, the term “substituted” means that an atom or group of atoms has replaced hydrogen as the substituent attached to another group.

As used herein, the term “optionally substituted” means that the referenced group may be substituted or unsubstituted. In one embodiment, the referenced group is optionally substituted with zero substituents, i.e., the referenced group is unsubstituted. In another embodiment, the referenced group is optionally substituted with an additional group selected from the groups described herein.

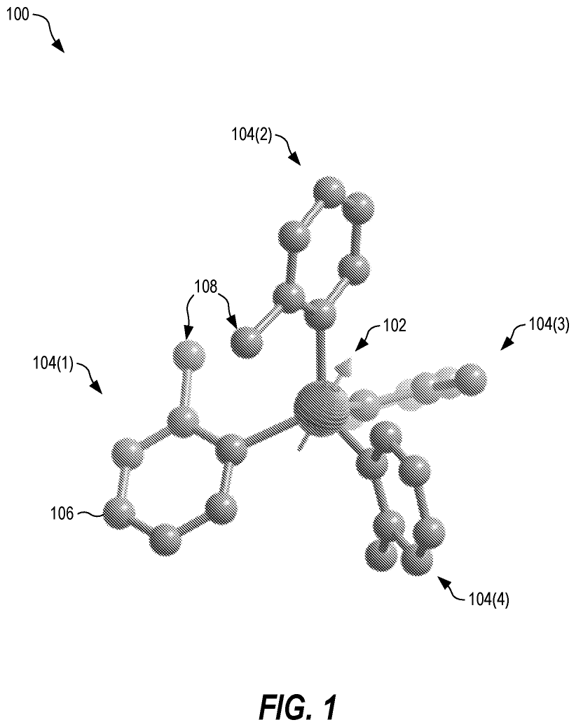

FIG. 1 shows of a coordination complex 100 formed from a plurality of ligands 104 bonded to a metal-atom center 102. In this example, the coordination complex 100 is represented by formula (II):

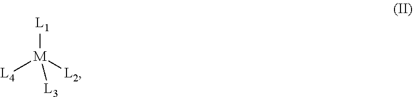

where M represents the metal-atom center 102 and L₁, L₂, L₃, and L₄ represent the four ligands 104(1), 104(2), 104(3), and 104(4). The coordination complex 100 may have more than four ligands 104, or fewer than four ligands 104, without departing from the scope hereof. The coordination complex 100 may also be referred to herein as a “metal-ligand complex”.

In the example of FIG. 1, the metal-atom center 102 is a single Cr⁴⁺ ion with a non-zero ground-state spin, and each of the four ligands 104(1), 104(2), 104(3), and 104(4) is an o-tolyl group that connects to the metal-atom center 102 at the 1-position and has a methyl group 108 connected to the 2-position. However, the example of FIG. 1 is non-limiting, and other types of metal-atom center 102 and ligands 104 may be used, as described in more detail below. For clarity in FIG. 1, each carbon atom 106 is depicted as a sphere, bonds between atoms are depicted as lines, and hydrogen atoms are not shown. The non-zero ground-state spin of the metal-atom center 102 is depicted with an arrow representing a rotational spin axis.

The ground-state Hamiltonian H of the coordination complex 100 is given by:

$$H = h D ( {S}_{z}^{2} - \frac{1}{3} S ( S + 1 ) ) + h E ( {S}_{x}^{2} - {S}_{y}^{2} ) + g {μ}_{B} \vec{B} \cdot \vec{S} \qquad ( 2 )$$

where D is the axial zero-magnetic-field energy splitting, E is the transverse zero-magnetic-field energy splitting, h is Planck's constant, \vec{S}=(Sᵣ, S_{y}, S_{Z}) is the vector of spin operators for total spin S, g is the electron g-factor, μ_{B} is the Bohr magneton, and \vec{B} is the applied magnetic field. The last term in Eqn. 1 gives rise to Zeeman shifts of magnetic sublevels. For the example of FIG. 1, where the metal-atom center is Cr⁴⁺, the total spin is S=1 and the total orbital angular momentum is L=0. However, the coordination complex 100 may have other non zero values for S and L. In Eqn. 2, hyperfine splitting (i.e., coupling to nuclear spins) is ignored for clarity.

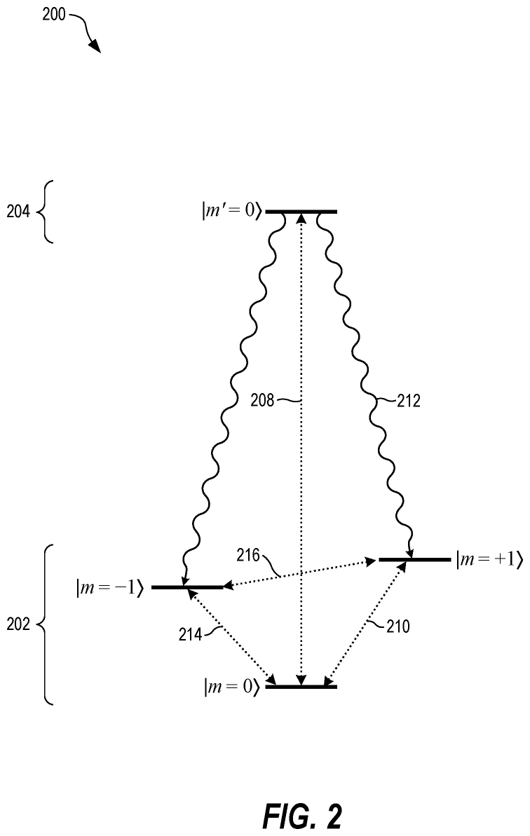

FIG. 2 is an energy-level diagram 200 of the coordination complex 100 of FIG. 1 for the example of Cr(o-tolyl)₄. The ground electronic state 202 is a spin-triplet state with magnetic sublevels |m=−1 [symbol] , |m=0 [symbol] , and |m=+1 [symbol] . Without the ligands 104 (i.e., a “bare” Cr⁴⁺ ion) and in the absence of an external magnetic field B, the three sublevels |m=−1 [symbol] , |m=0 [symbol] , and |m=+1 [symbol] are degenerate. However, the ligands 104, when bonded to the Cr⁴⁺ ion, reduce the symmetry of the Cr⁴⁺ ion, which lifts this degeneracy at zero field. As a result, the first sublevel |m=0 [symbol] has a lower energy than the second sublevel |m=−1 [symbol] , and the second sublevel |m=−1 [symbol] has a lower energy than the third sublevel |m=+1 [symbol] . When the sign of D is flipped, then the third sublevel |m=+1 [symbol] will have a lower energy than the second sublevel |m=−1 [symbol] . The first and second sublevels may be coupled via a first spin transition 214 with Δm=−1, and the first and third sublevels may be coupled via a second spin transition 210 with Δm=+1. The energy spacing between the second and third sublevels corresponds to the parameter E in Eqn. 2, while the energy spacing between the first sublevel and the weighted center of the second and third sublevels corresponds to the parameter D in Eqn. 2. For the example of Cr(o-tolyl)₄, E<<D, and therefore the spin transitions 210 and 214 are not drawn to scale in FIG. 2.

For many examples of the coordination complex 100, the parameter D has a value in the range between 0.5 and 10 GHz, and therefore the spin transitions 210 and 214 can be driven via microwaves. These values of D advantageously allow the coordination complex 100 to be integrated with compact, low-power microwave components (i.e., circuit components, waveguides, antennas, etc.), such as those used for telecommunications (e.g., 4G, 5G, LTE, etc.), wireless networking (e.g., Wi-Fi), RFID, and wireless tracking (e.g., ultra-wide band). However, the coordination complex 100 may have a value of D that is less than 0.5 GHz, or greater than 10 GHz, without departing from the scope hereof Thus, any reference to “microwaves” herein is not limited to electromagnetic radiation in the microwave region of the electromagnetic spectrum (i.e., 300 MHz-300 GHz), and therefore may include millimeter waves, radio waves, terahertz radiation, and other frequency regions of the electromagnetic spectrum.

The coordination complex 100 also has an excited state 204 that can be accessed from the ground electronic state 202 via an optical transition 208. For the example of Cr(o-tolyl)₄, the excited state 204 is a spin-singlet state (i.e., with total spin S=0) with one magnetic sublevel having a magnetic spin quantum number m′=0. The excited state 204 can decay, via spontaneous emission 212, to the first, second, and third ground-state magnetic sublevels |m=−1 [symbol] , |m=0 [symbol] , and |m=+1 [symbol] . For clarity in FIG. 2, only decay to the second and third ground-state sublevels is shown. Similarly, the optical transition 208 is shown between the first sublevel |m=0 [symbol] and the excited state 204, for which Δm=0. The corresponding optical transition between the second sublevel |m=−1 [symbol] and the excited state 204 has Δm=+1, while the corresponding optical transition between the third sublevel |m=+1 [symbol] and the excited state 204 has Δm=−1.

The energy spacing between the ground state 202 and the excited state 204 may lie in the infrared, optical, or ultraviolet regions of the electromagnetic spectrum. Accordingly, the optical transition 208 may be driven, for example, by the coherent output of a laser or the incoherent output of a lamp or discharge tube. For many examples of the coordination complex 100, the optical transition 208 coincides with a wavelength band used for telecommunications (e.g., the O-band between 1260 and 1360 nm, the C-band between 1530 and 1565 nm, etc.) or a nearby wavelength range (e.g., 1000-1100 nm). Such wavelengths advantageously allow the coordination complex 100 to be used with compact lasers and optical components widely available for optical communications.

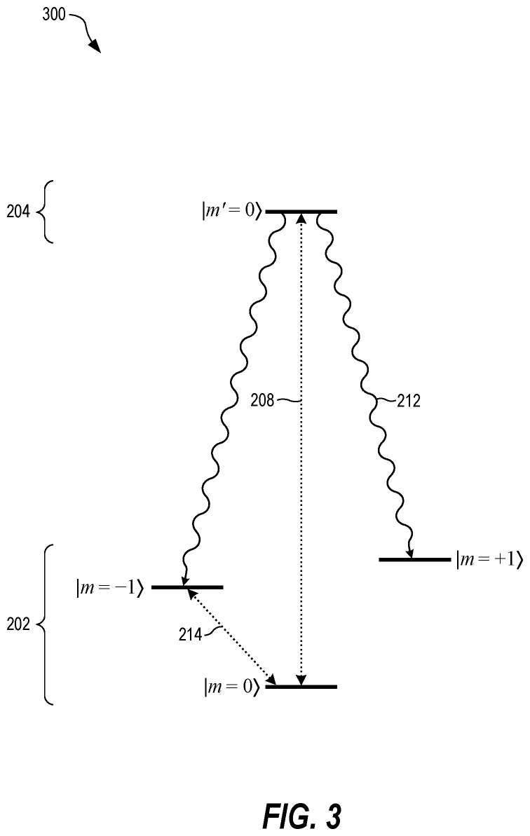

FIG. 3 illustrates a method 300 for spin polarizing the coordination complex 100 of FIG. 1. Prior to spin polarizing, a population of the coordination complex 100 may be distributed equally among the three ground-state magnetic sublevels |m=−1 [symbol] , |m=0 [symbol] , and |m=+1 [symbol] due to thermalization, wherein the coordination complex 100 is unpolarized. A linearly polarized laser field drives the optical transition 208, optically pumping the coordination complex 100 into the second magnetic sublevel |m=−1 [symbol] and the third magnetic sublevel |m=+1 [symbol] , thereby depleting the population of the first magnetic sublevel |m=0 [symbol] and partially spin polarizing the coordination complex 100. To accrue spin polarization, a spin-lattice relaxation time of the ground state 202 is greater than a lifetime of the excited state 204.

To more fully spin polarize the coordination complex 100, a microwave field may drive the first spin transition 214 to transfer the population of the second sublevel |m=−1 [symbol] to the first sublevel |m=0 [symbol] such that optical pumping can continue. In this embodiment, all population is transferred to the third sublevel |m=+1 [symbol] , which is “dark” to the microwave and laser fields. Alternatively, a microwave field may drive the second spin transition 210 to transfer the population of the third sublevel |m=+1 [symbol] to the first sublevel |m=0 [symbol] , wherein the all population is transferred to the second sublevel |m=−1 [symbol] .

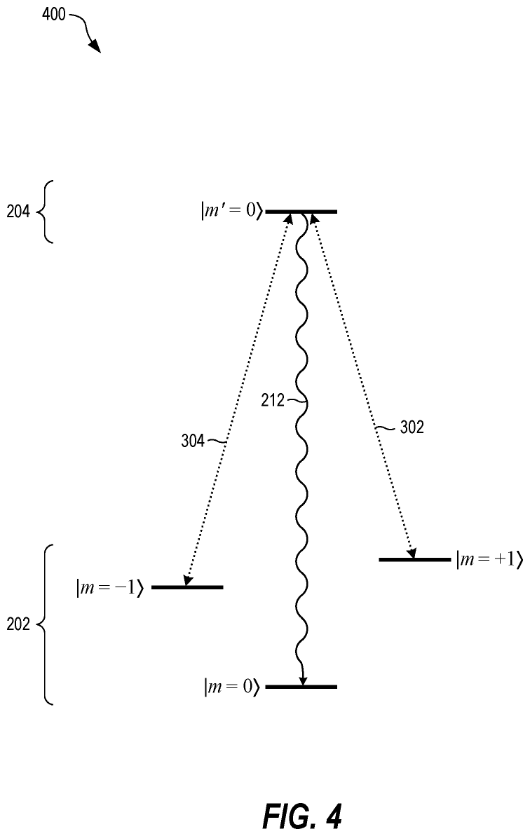

FIG. 4 illustrates a method 400 for spin polarizing the coordination complex 100 of FIG. 1 into the first sublevel |m=0 [symbol] . A first laser field 302 couples the second sublevel |m=−1 [symbol] to the excited state 204 while a second laser field 304 simultaneously couples the third sublevel |m=+1 [symbol] to the excited state 204. The excited state then decays into the first sublevel |m=0 [symbol] , the second sublevel |m=−1 [symbol] , or the third sublevel |m=+1 [symbol] . This process continues, wherein the population accumulates in the first sublevel |m=0 [symbol] , which is dark to the laser fields 302 and 304. Alternative to using the two laser fields 302 and 304, a single-frequency laser field and single-frequency microwave field may be used.

In FIG. 4, the laser fields 302 and 304 may be generated from two separate lasers, or by frequency modulating the output of a single-frequency laser at the parameter E, which will produce sidebands displaced from the optical carrier by E (and harmonics). For the example of Cr(o-tolyl)₄, E is so small that it cannot be spectrally resolved, i.e., E is less than a linewidth of the optical transition 208. In this case, there is no need to frequency modulate the laser, as a single-frequency laser can serve as both of the laser fields 302 and 304. Alternatively, an external magnetic bias field may be added to remove the degeneracy of the second and third magnetic sublevels when E is near zero.

Once the coordination complex 100 is spin-polarized, it may be coherently controlled by driving either one of the first and second spin transitions 210 and 214. Furthermore, when the parameter E is non-zero, a third spin transition 216 between the second sublevel |m=−1 [symbol] , or the third sublevel |m=+1 [symbol] can be driven. For example, if the coordination complex 100 is fully spin polarized in either the first sublevel |m=0 [symbol] or the second sublevel |m=−1 [symbol] , then a microwave field can be applied to drive the first spin transition 214. The microwave field may have the form of a pulse that places the coordination complex 100 in a superposition of the first and second sublevels. In this case, the coordination complex 100 forms a qubit that uses the first and second sublevels as quantum-computational basis states. Alternatively, if the coordination complex 100 is fully spin polarized in either the first sublevel |m=0 [symbol] or the third sublevel |m=+1 [symbol] , then a microwave field can be applied to drive the second spin transition 210, in which case the coordination complex 100 forms a qubit that uses the first and third sublevels as quantum-computational basis states. When the coordination complex 100 is fully spin polarized in the first sublevel |m=0 [symbol] , two microwave fields can be applied to simultaneously drive both spin transitions 210 and 214, wherein the coordination complex 100 forms a qutrit that uses the first, second, and third magnetic sublevels as basis states.

In some embodiments, two-frequency laser fields that are detuned from the optical transition 208 are used to coherently transfer the population of the coordination complex 100 between the first, second, and third sublevels using stimulated Raman transitions.

Chemical Tunability

The type of metal-atom center 102, number of ligands 104, and type of ligands 104 may be selected to modify the structure of the coordination complex 100. This ability to modify the structure of the coordination complex 100 is referred to herein as “chemical tunability”. Chemical tunability may be used to modify the following properties of the coordination complex: (i) the zero-phonon wavelength, (ii) the phonon sideband spectrum, (iii) the off-resonant absorption profile, (iv) the energies of the excited state 204 and other higher-energy excited states, (v) the axial zero-field splitting D, and (vi) the transverse zero-field splitting E. The ability to chemical tune the zero-field splitting E is particularly important since it may be used to increase the spin coherence time.

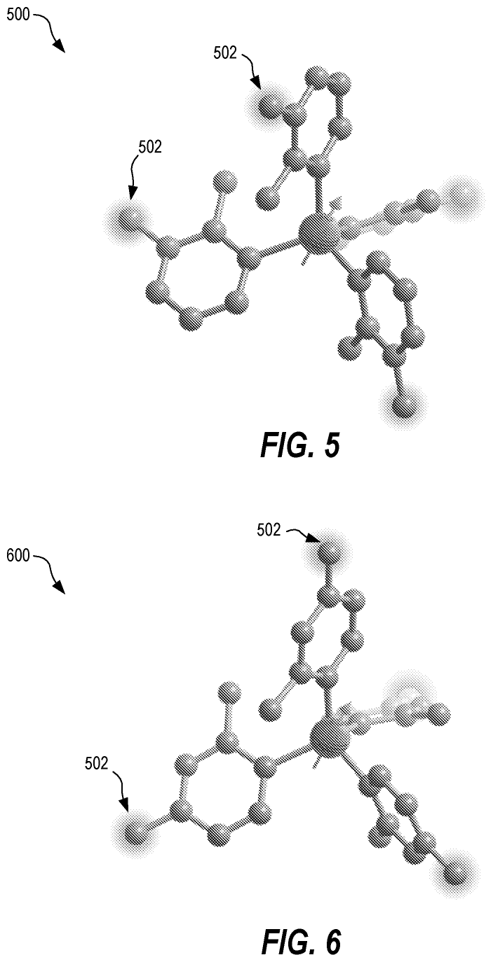

As an example of chemical tunability, FIG. 5 shows a coordination complex 500 that is similar to the coordination complex 100 of FIG. 1 except that an additional methyl group 502 has been added to each of the ligands 104 at the 3-position of the corresponding carbon ring. Thus, the coordination complex 500 has the formula Cr(2,3-dimethylphenyl)₄. The coordination complex 500 has a similar energy-level structure to that of Cr(o-tolyl)₄ (see FIG. 2) except that D≈1.8 GHz, E≈0.48 GHz, and the energy of the optical transition 208 is shifted. Thus, the coordination complex 500 shows one example of how the ligands 104 can be chemically modified to change its energy-level structure.

FIG. 6 shows a coordination complex 600 that is similar to the coordination complex 500 of FIG. 5, except that the additional methyl group 502 has been added to each of the ligands 104 at the 4-position of the corresponding carbon ring. Thus, the coordination complex 600 has the formula Cr(2,4-dimethylphenyl)₄. The coordination complex 600 has a similar energy-level structure to that of Cr(o-tolyl)₄ (see FIG. 2) except that D≈4.1 GHz, E 0.52 GHz, and the energy of the optical transition 208 is shifted. The coordination complex 600 shows another way in which the ligands 104 can be chemically modified to change the energy-level structure.

While the above discussion shows an example of the coordination complex 100 with a spin-triplet ground state 202 and spin-singlet excited state 204, it should be understood that the coordination complex 100 may be alternatively structured (e.g., by choice of the metal-atom center 102 and the number and type of ligands 104) to have different non-zero spin. In fact, the present methods may be used with any coordination complex 100 whose ground-state angular momentum is non-zero (e.g., S=½, 1, 3/2, 2, etc.), wherein the number of ground-state sublevels is equal to 2S+1. Non-zero ground-state angular momentum may arise from any combination of orbital angular momentum, electron spin, and nuclear spin, and gives rise to at least two ground-state magnetic sublevels that can be utilized as a qubit. Similarly, the excited state 204 can have any angular momentum, wherein the laser field can be modified (e.g., by choice of frequencies and optical polarizations) to polarize the ground state via optical pumping.

While the coordination complex 100 is shown in FIG. 1 as forming a pseudo-tetrahedral arrangement, the coordination complex 100 may alternatively form a different arrangement (e.g., trigonal, trigonal bi-pyramidal, octahedral, etc.). Similarly, while the coordination complex 100 is described above for the case where the metal-atom center 102 is a Cr⁴⁺ ion, the metal-atom center 102 may alternatively be a different species of metal. For example, the metal-atom center 102 may be selected from another atomic species in Group 6 of the periodic table (e.g., molybdenum, tungsten, etc.). The metal-atom center 102 may also be selected from a different group of metals in the periodic table. For example, the metal-atom center 102 may be a V⁴⁺ ion (with total ground-state spin S=½), or another metal from Group 5. The metal-atom center 102 may also be selected to have an oxidation state other than +4. For example, the metal-atom center 102 may be a V³⁺ ion, which has an oxidation state of +3. While the Cr⁴⁺ ion has a d² electronic configuration, an alternative choice for the metal-atom center 102 may result in a different electronic configuration. For example, the metal-atom center 102 may be a Mo⁵⁺ ion (with total ground-state spin S=½), which has a d¹ configuration and an oxidation state of +5, or a Ni²⁺ ion, which has a d⁸ configuration.

Each of the ligands 104 may be a monodentate ligand independently selected from the group consisting of cyano, nitro, amido, aryl, deuterated aryl, heteroaryl, and deuterated heteroaryl. The aryl, deuterated aryl, heteroaryl, and deuterated heteroaryl may be optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, deuterated C₁₋₆ haloalkyl. All of the ligands 104 may be identical, as is the case for the coordination complexes 100, 500, and 600. However, the ligands 104 may be different without departing from the scope hereof.

In embodiments, a metal-ligand complex has a structure according to formula (I)

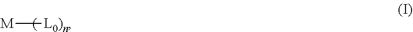

where M is selected from the group consisting of Ti²⁺, V³⁺, Cr₄₊, Mo⁴⁺, W⁴⁺, Mn⁴⁺, Fe²⁺, Co¹⁺, and Ni²⁺. Furthermore, each occurrence of L₀ represents a monodentate ligand independently selected from the group consisting of cyano, nitro, amido, aryl, deuterated aryl, heteroaryl, and deuterated heteroaryl. Said aryl, deuterated aryl, heteroaryl, and deuterated heteroaryl may be optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl. The number n of ligands may be 4, 5, or 6. Some examples of these embodiments include (i) M is V³⁺ and n is 4 or 5, (ii) M is Cr⁴⁺ and n is 4, (iii) M is Mo⁴⁺, and n is 4, (iv) M is W⁴⁺ and n is 4, and (v) M is Ni²⁺ and n is 6.

In some of the above embodiments, the metal-ligand complex has a structure according to formula (III):

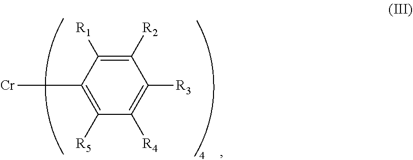

where each of R₁, R₂, R₃, R₄, and R₅ is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl.

Different types of the coordination complex 100 may be used concurrently within a single sample (e.g., see the dilute crystal 700 of FIG. 7). Each type of coordination complex has different properties that allow for imaging with a single laser spot via one or both of wavelength multiplexing and magnetic-resonance multiplexing. Multi-metal center coordination complexes can also be engineered with different values of D and E to be individually addressable.

Dilute Crystals

FIG. 7 shows a dilute crystal 700 formed by diluting a plurality of the coordination complex 100 of FIG. 1 within a host. In the example of FIG. 7, the host is a plurality of spin-zero coordination complexes 702. When the coordination complex 100 is Cr(o-tolyl)₄, each spin-zero coordination complex 702 may be an isostructural tin (Sn) analogue, i.e., Sn(o-tolyl)₄. That is, each spin-zero coordination complex 702 may be the same as the coordination complex 100 except that the metal-atom center 102 is replaced with a metal-atom center 704 of a different atomic species. The lack of ground-state spin in each metal-atom center 704 is indicated in FIG. 7 by the absence of an arrow representing a rotational spin axis. Other host materials may be used without departing from the scope hereof. In particular, other spin-zero isostructural analogues may be used, such as Sn(2,3-dimethylphenyl)₄ or Sn(2,4-dimethylphenyl)₄.

The host material may be any compound that is transparent both at the wavelength used to excite the optical transition 208, and at the microwave frequencies used to drive the spin transitions 210, 214, and 216. Examples of other host materials include germanium, silicon, titanium, and their analogs (e.g., Ge(2,3-dimethylphenyl)₄). The host material can also be amorphous (i.e., non-crystalline) or polycrystalline solid, or a liquid. In other embodiments, the coordination complex 100 is deposited on a surface. In other embodiments, the coordination complex 100 is physically suspended (e.g., via optical tweezers).

The host material is used to separate the coordination complexes 100, thereby ensuring that the coordination complexes 100 are spaced far enough from each other to minimize any interaction therebetween. In embodiments, a ratio of a first coordination complex 100 (e.g., Cr(o-tolyl)₄) to a second coordination complex 100 (e.g., Sn(o-tolyl)₄) is less than or equal to 1%. A higher ratio advantageously increases the number of the coordination complexes 100 used for a quantum application (e.g., sensing), but increases the likelihood of coordination complexes 100 interacting with each other. Such interactions may reduce spin-coherence time and/or spin-relaxation times.

In embodiments, a crystal includes coordination complexes of two different structures, the first structure being represented by formula (III):

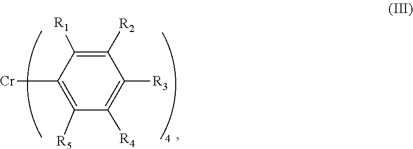

and the second structure being represented by formula (IV):

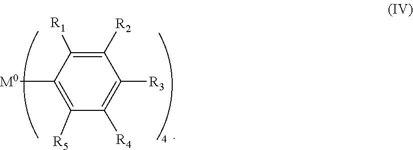

The metal-atom center M⁰ may be selected from the group consisting of Sn⁴⁺, Ge⁴⁺, Si⁴⁺, Ti⁴⁺ Fe⁴⁺, Ru⁴⁺, and Os⁴⁺. However, the metal-atom center M⁰ may be another type of atom without departing from the scope hereof. For each occurrence, R₁ is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl. For each occurrence, R₂ is uniformly selected from the same group. For each occurrence, R₃ is uniformly selected from the same group. For each occurrence, R₄ is uniformly selected from the same group. For each occurrence, R₅ is uniformly selected from the same group. In some of these embodiments, the ratio of chromium to M⁰ is less than or equal to 10%. In some of these embodiments, the ratio of chromium to M⁰ is less than or equal to 1%. The metal-atom center M⁰ may be tin.

Spin Manipulation Techniques

Spin manipulation techniques may be implemented with the coordination complexes of the present embodiments (e.g., coordination complexes 100 and 500) for a variety of applications, such as quantum computing and information processing, quantum communication, sensing (e.g., magnetic fields), and timekeeping. For example, Ramsey interferometry may be implemented with the coordination complex 100 to create a magnetic-field sensor or frequency reference. Specifically, one of the methods 400 and 500 may be used to spin polarize the coordination complex 100 into one of the three magnetic sublevels of the ground electronic state 202. A first π/2 pulse (e.g., a πₓ/2 or π_{y}/2 pulse) is then applied to transfer the spin-polarized coordination complex 100 into an equal (or nearly equal) superposition of two of the three ground-state magnetic sublevels. The coordination complex 100 (in the superposition state) then freely precesses (i.e., in the absence of any intentional driving fields) for an interrogation time, after which a second π/2 pulse stops the precession by projecting the resulting quantum state onto a measurement basis. The phase accumulated by the coordination complex 100 during precession is then measured, such as by detecting photoluminescence (e.g., resonance phosphorescence) emitted by the coordination complex 100 during optical pumping. Since the two ground-state magnetic sublevels of the superposition have energies that depend on magnetic field in different ways, the accumulated phase scales with the magnetic field, thereby providing a way to convert the measured phase into a value of the magnetic field.

Dynamical decoupling is another example of a spin manipulation technique that may be used with the present coordination complexes. Used for extending coherence times, dynamical decoupling may be implemented by first using the method 300 or 400 to spin polarize the coordination complex 100. A π/2 pulse is then applied to transfer the spin-polarized coordination complex 100 into an equal (or nearly equal) superposition of two of the three ground-state magnetic sublevels. Subsequent π pulses are then applied to rephase the coordination complex 100, thereby canceling dephasing noise.

Dynamical decoupling may be used to measure an AC magnetic field. For example, the method 300 or 400 may first be used to spin polarize the coordination complex 100, followed by π/2 pulse that transfers the spin-polarized coordination complex 100 into an equal (or nearly equal) superposition of two of the three ground-state magnetic sublevels. The interval of π pulses is scanned, wherein the accumulated phase is maximized when the frequency of the π pulses matches the frequency of the AC magnetic field. The readout is the same as that for Ramsey interferometry, as described above.

Optical relaxometry is another quantum manipulation technique that may be used with the present coordination complexes. Specifically, the method 300 or 400 may first be used to spin polarize the coordination complex 100, after which the coordinate complex 100 freely precesses. After some time, the spin polarization is measured, from which a depolarization fraction can be determined (i.e., the fraction of the initial polarization lost during the wait time). This depolarization can be correlated, for example, with a local spin bath or other properties of the environment surrounding the coordination complex 100.

Optical DC magnetic-field sensing is another application that may be used with the present coordination complexes. Here several optical fields (e.g., lasers) have frequencies and polarizations selected to resonantly couple the ground-state magnetic sublevels to the excited state 204 in the absence of an external magnetic field. In this case, resonant excitation and spontaneous decay is maximized, leading to a greatest amount of detected photoluminescence. As the external magnetic field is increased, the |m=+1 [symbol] and |m=−1 [symbol] ground-state magnetic sublevels will be Zeeman-shifted out of resonance with their lasers, resulting in a decrease in detected photoluminescence. Thus, the amount of detected photoluminescence can be converted into a value of the external magnetic field.

Zeeman splittings of the ground state 202 may be used to optically measure an unknown external magnetic field. The coordination complex may be driven with optical fields (e.g., lasers) whose frequencies are constrained to match known values of the parameters D and E. In this case, there is only one free relative laser-frequency parameter that can be experimentally adjusted to maximize the detected photoluminescence. The value of the free parameter at which this maximization occurs then determines the Zeeman splitting, from which a value of the external magnetic field can be determined.

Incorporating Coordination Complexes

The coordination complexes of the present embodiments may be deposited onto a surface, mixed into a fluid or material, or otherwise incorporated into a device or structure using any of several incorporation techniques. Examples of these incorporation techniques include:

Evaporation: A sample of the coordination complexes may be heated in a vacuum chamber to deposit the coordination complexes layer-by-layer on a surface. Heterostructures (lateral or vertical) with different types of coordination complexes can be fabricated as layers, where the layers are formed in a desired order and each layer has a desired thickness.

Dropcast: A sample of coordination complexes may be dissolved in a solvent, or incorporated in a polymer (e.g., polystyrene, PMMA, photoresist, etc.), that may be dropped on a surface.

Spin-coated: A substrate may be spun after or during dropcasting such that coordination complexes deposited thereon form an evenly coated layer of variable thickness depending on the solution or spin-coating conditions.

E-beam: A polymer with integrated coordination complexes may be patterned using e-beam lithography to create structures.

Photo-lithography: A photoresist with integrated coordination complexes may be patterned using standard photolithography techniques to create structures.

Inkjet printing: An ink containing coordination complexes may be used to print structures with zero, one, two, or three spatial dimensions.

Non-isostructural matrices: Coordination complexes may be bonded (either covalently or noncovalently) to non-isostructural matrices.

Microfluidics: Coordination complexes may be used with a fluid flowing through microfluidic devices. For example, the coordination complex may be dissolved in the fluid such that the coordination complexes flow through the microfluidic devices with the fluid.

Spray coating: Coordination complexes may be sprayed on a surface.

Paint: Coordination complexes may be added to paint that is applied to a surface.

Functionalization: Coordination complexes may be specifically functionalized for to attach to biomolecules. The coordination complexes may also be functionalized to gold or other surfaces to precisely incorporate the coordination complexes into devices (e.g., electronic, photonic, phononic, plasmonic, etc.).

Photonic devices: Any of the above techniques may be used to incorporate coordination complexes with a photonic device, advantageously improving emission from a cavity of the photonic device (e.g., by modifying excited state lifetime).

Applications

The present embodiments may be used for the following applications:

Emissive Labeling: Coordination complexes may be used as bio-markers by functionalizing them. The number of distinct measurements in a system can be increased by wavelength multiplexing by tailoring emission wavelength. Optically detected magnetic resonance may be used to improve signal-to-noise ratio, and therefore sensitivity. Coordination complexes engineered to have different values of D and E, even if they share the same emission band, can increase the number of distinguishable biomarkers using optically-detected magnetic resonance. These coordination complexes may be used with biomarker sensing techniques known in the art, such as ELISA, lateral flow assay, fluorescent microscopy, and flow cytometry.

Spin-Density Sensors: The spin-relaxation time T₁ decreases as the nearby spin density increases. The spin-relaxation time T₁ can be measured all optically (i.e., without any microwaves), thereby enabling non-invasive remote measurements of local spin density. This capability may be particularly useful for measuring ambient paramagnetic molecules such as oxygen, Lewis basic chemical analytes (ammonia, phosphine, etc.), radicals, and magnetic beads. All-optical measurements of the spin-relaxation time T₁ may also be useful for functionalized molecules clustering. For example, the density of a certain biomarker on a structure (e.g., Ca, K channels on a neuron cell wall) may be measured. As another example, chemical binding may be tested by first attaching coordination complexes to a drug and its target, and then measuring the change in T₁ to determine clustering due to binding success.

Nanometer-Scale Superresolution Magnetic-Field Sensors: Coordination complexes may be deposited (e.g., using any of the incorporation techniques above) to form an array of “pixels”, where each pixel is itself a one, two, or three-dimensional array of coordination complexes of different types (i.e., that emit at different wavelengths). Each pixel spans a predetermined length scale, and is therefore individually addressable by a single laser beam. Different wavelengths originate from a different known location with the pixel, and therefore wavelength multiplexing of the emission can be used to measure an external magnetic field with sub-pixel resolution that is less than the optical diffraction limit.

For example, consider a linear sequence of n coordination complexes that are uniformly spaced by, for example, 200 nm. Each coordination complex emits at a different wavelength, and the order of these emission wavelengths is known. By using ODMR to measure each of these coordination complexes, the resulting measurements can be combined to determine the magnetic field gradient with a 200-nm spatial resolution, beyond the optical diffraction limit.

Nanometer-Scale Superresolution Rulers: Coordination complexes with individual addressability can be functionalized to attach to a sensing target. The resulting system may be placed in a non-uniform, but known, magnetic field (e.g., produced by a nearby wire). This magnetic field may have been previous calibrated using the above device. With knowledge of the magnetic-field vector (i.e., magnitude and direction of the magnetic field), and a measurement of the Zeeman splitting of the unknown molecules independently, the relative distances and orientations of the coordination complexes can be measured with nanometer resolution.

pH Sensing: Functional groups with labile protons (e.g., OH, NH₂) may be attached to coordination complexes to alter one or both of their symmetry and ligand field strength depending on the local pH (e.g., through protonation or deprotonation of the functional group), This shifts the zero-phonon line energy as well as the D and E parameters.

MRI Contrast Agents: Coordination complexes may be introduced in an environment to dynamically polarize nearby nuclear spins (e.g., hydrogen), advantageously allowing for polarization beyond what is thermally available. This also reduces the need for large magnetic fields and/or increasing the MRI resolution.

Small-Volume NMR: Coordination complexes may be functionalized to attach to a molecule or surface of interest. The sensing target may include atoms with naturally occurring nuclear spins that Larmor precess under a fixed magnetic field, thereby generating an AC magnetic field. This AC magnetic field can be detected with the dynamical decoupling technique discussed above. The detected signal may be used to determine the type of the sensed atom as well its distance to the coordination complex, allowing for three-dimensional atomistic reconstruction of the target.

Environment Sensing: The ligand symmetry, the relative strengths of the ligands, and the total ligand strength determine the zero-phonon line energy, the D parameter, and the E parameter. By measuring changes to these properties, coordination complexes may be used to sense an external electric field when the ligands have internal electric dipole moments that couple to this electric field. Coordination complexes may similarly be used to sense strain since ligands deform under strain, or to sense pressure since ligands compress under pressure. Coordination complexes may also be used to sense temperature since the ligands can elongate with increased temperature, and since the phonon structure (or vibrational profile) changes with temperature. The spin relaxation also changes with temperature and can be used as a way to measure it.

Entanglement-Improved Sensing: A multi-metal center coordination complex, where each coordination complex has individual addressability (as described above) may be used to improve sensitivity beyond classical limits. Dipolar or exchange coupling between multiple metal centers can be used to entangle their electronic spins. This entangled wave function is more sensitive to magnetic fields than the sum of the individual spins acting alone, allowing for improved sensitivity. A multi-metal-entangled metal center can be substituted for any magnetic field sensing techniques described herein.

Wide Field Surface Scanning: Coordination complexes may be applied to a surface, or located inside an environment, using any of the incorporation techniques described above. A widefield imaging setup may be used to probe the behavior of the coordination complexes within the spot-size resolution to sense one or more of magnetic field, ambient spin density, electric field, strain, pressure, temperature, and pH.

Sub nm-Scanning Probe: Coordination complexes may be placed on the tip of a confocal microscopy scanning probe setup to measure, with sub-nanometer resolution, one or more of magnetic field, ambient spin density, and electric field.

Fiberoptic Probe: Coordination complexes may be applied to the tip of a fiberoptic cable (e.g., using any of the incorporation methods described above). The fiberoptic cable guides the light that initializes and readouts the coordination complexes. Such a device could be used to sense one or more of magnetic field, ambient spin density, electric field, pressure, strain, and temperature.

Optically-Pumped Maser: An ensemble of molecular-spin qubits (i.e., a population of coordination complexes) may be placed in a microwave or millimeter-wave cavity (e.g., using any of the incorporation methods described above) to form a maser. The energy of the spin transitions can be tuned (e.g., using any of the technique or methods described herein) such that it matches a resonance of the cavity. An optical drive field may then be used to optically polarize the ensemble to the higher-energy spin sublevel (e.g., the sublevel |m=+1 [symbol] in FIG. 2) When the population in this higher-energy sublevel exceeds a threshold, the system will amplify microwave or millimeter-wave radiation via stimulated emission.

A Laser Threshold Magnetometer: An ensemble of molecular-spin qubits may be placed in an optical cavity (e.g., using any of the incorporation methods described above). The molecular-spin qubits or the optical cavity may be tuned or configured such that the zero-phonon line is resonant with a resonance of the optical cavity. A constant radio, microwave or millimeter-wave drive may then be applied to the molecular-spin qubits. However, whether the drive is resonant with the ground-state spin sublevels depends on an external magnetic field. Population inversion just below or above the lasing threshold of the ensemble can be achieved with an off-resonant pump. The system may have a spin-selective excitation that could be achieved with one of the techniques described above. Under the above conditions (i.e., near threshold and spin selective excitation), the ensemble has a steady-state response with a ground-state spin polarization. A change in the ground-state population caused by a change in the external magnetic field changes the ground-state levels to be in or out of resonance with the driving field, depending on the initial condition. This, in turn, changes the amount of pumped population turning the lasing on or off depending on which side of the lasing threshold the initial conditions occur.

Quantum Optical Memory: An inhomogeneously broadened ensemble of molecular-spin qubits may be placed or incorporated within an optical cavity (e.g., using any of the incorporation methods described above). A single photon may be stored within this ensemble to be remitted at a later time using one or more of electromagnetically-induced transparency, the Duan-Lukin-Cirac-Zoller (DLCZ) protocol, an atomic frequency comb, controlled reversible inhomogeneous broadening (CRIB), and off-resonant Faraday interaction.

Integration Within Classical Electronic Devices: Traditional electronic or optoelectronic devices (e.g., integrated circuits, MEMS, photonic circuits, etc.) may be built using techniques known in the art. These devices may be fabricated with pads, or other organic or inorganic substances, that coordination complexes can be functionalized to selectively attach to. In this manner, the coordination complexes can be easily introduced in a targeted, and therefore scalable, fashion for device integration. An optical, electronic, or optoelectronic circuit with integrated molecular-spin qubits may be used to construct many types of devices, some examples of which are described below.

Quantum Repeater Node: A molecular-spin qubit or multi-metal center collection can be integrated into a photonic cavity (e.g., using a technique described above) to form a quantum repeater note. The emission wavelength of the molecular-spin qubit may be tuned using one or more of electric gates, strain, and pressure to match a specific frequency within the cavity resonance. Indistinguishable emission from two such quantum repeater nodes can be interfered, either with fiber optics or in free space) to create spin entanglement therebetween. The coherence of entangled electronic states may be extended by swapping the wavefunction to a nearby nuclear spin with a longer coherence time, or by running an error correction algorithm. The error correction algorithm may use nearby nuclear spins, other electronic spins of a multi-metal-center architecture (if present), or a combination thereof. Multiple such clusters with different wavelengths can be built within a device to create more communication channels.

A Digital Quantum Information Processing Device: A one-, two-, or three-dimensional multi-qubit architecture may be constructed according to any of the frameworks described above. Each molecular-spin qubit in the architecture may be individually initialized and measured within a laser spot using wavelength multiplexing, magnetic multiplexing, or a combination thereof. Each molecular-spin qubit may be individually controlled using zero-field splitting (i.e., the parameters D and E) multiplexing as each microwave rotation will only address one molecular-spin qubit, depending on its unique magnetic parameters. The wavelengths and parameters D and E may also be tuned by local electric gates. The orientation and distance of the molecular-spin qubits with respect to the drive field can also be tuned (e.g., with a helical design), in which case the drive field orientation or duration can further increase the individual addressability. Two qubit gates can be realized by magnetic dipolar coupling, exchange interaction coupling, or the dynamical coupling technique described above. Nuclear spins may also be used as additional qubit registers for computation or long data storage.

An Analog Quantum Information Processing Device: A one-, two-, or three-dimensional multi-qubit architecture may be constructed according to any of the frameworks described above. Each molecular-spin qubit in the architecture may be individually initialized and measured within a laser spot using wavelength multiplexing, magnetic multiplexing, or a combination thereof. Each molecular-spin qubit may be individually controlled using zero-field splitting (i.e., the parameters D and E) multiplexing as each microwave rotation will only address one molecular-spin qubit, depending on its unique magnetic parameters. The wavelengths and parameters D and E may also be tuned by local electric gates.

The total Hamiltonian of the system may be engineered, for example, by using a uniform or a non-uniform magnetic field to Zeeman-split ground-state magnetic sublevels. Alternatively, the distance and relative orientation between the molecular-spin qubits could be adjusted to set the dipolar or exchange coupling. After initialization, the system evolves in time and individual molecular-spin qubits may be measured at a later time to observe the ground state, and therefore the solution of this Hamiltonian of interest. For example, such a system could be used to solve an Ising problem for a designed Hamiltonian.

The above applications may be combined. For example, one of the above-mentioned quantum repeater nodes may be connected to one of the above-mentioned quantum sensors. This combined system could be additionally connected to either the digital or analog quantum information processing device described above. Other such combinations are included in the scope hereof.

Experimental Demonstration

Optically addressable solid-state spins are an important platform for quantum information science, with impressive demonstrations ranging from quantum teleportation to the mapping of individual nuclear spins. The optical-spin interface of these solid-state systems is crucial for a diverse range of applications, from nanoscale sensing to long-distance quantum communication, as it enables straightforward single-spin readout and initialization. However, for this family of qubits, synthetic tunability of optical and spin properties, deterministic fabrication of multi-qubit arrays, and translation of spin centers between different host materials and devices remain outstanding goals.

By contrast, chemical synthesis of molecular spin systems affords bottom-up qubit design. A chemical approach offers tunability through atomistic control over the qubit, scalability via chemical assembly of extended structures, and portability across different environments (e.g., solution, surface, solid-state) since the qubit is not confined to a specific host. These capabilities provide remarkable control over the intrinsic and extrinsic environment of molecular qubits. Notably, with chemical synthesis, nuclear spins can be controllably placed around a molecular qubit, arrays of spins can be created in 1-, 2- and 3-dimensional architectures, and molecular spins can be integrated into electronic and photonic devices. Molecular systems have shown impressive demonstrations including long spin coherence, manipulation of photoexcited triplet states, and quantum optics with spin-singlet (S=0) organic molecules. However, in contrast to spins in semiconductors, the ground-state spin of molecular systems has lacked an optical-spin interface for both qubit initialization and readout.

Here, through bottom-up design, we demonstrate synthesis of a series of tunable molecular qubits with such an optically addressable ground-state spin. We show that these molecular spin qubits can be initialized and read out with light, and coherently manipulated with microwave fields. By tuning both their optical and spin properties through control of molecular structure, we demonstrate the power of bottom-up qubit creation.

To achieve optical addressability, we target a tunable molecular system consisting of a metal ion bonded to organic moieties (ligands), forming a portable qubit of ˜1 nm size. This organometallic motif provides a well-defined qubit through the electronic spin of the central metal ion, with highly controllable ligands surrounding the metal to offer synthetic tunability.

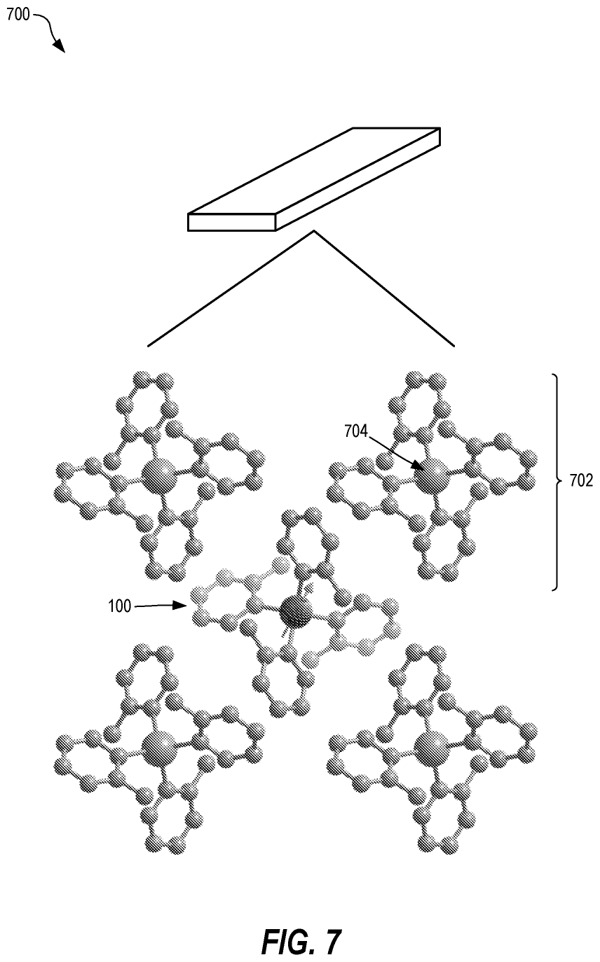

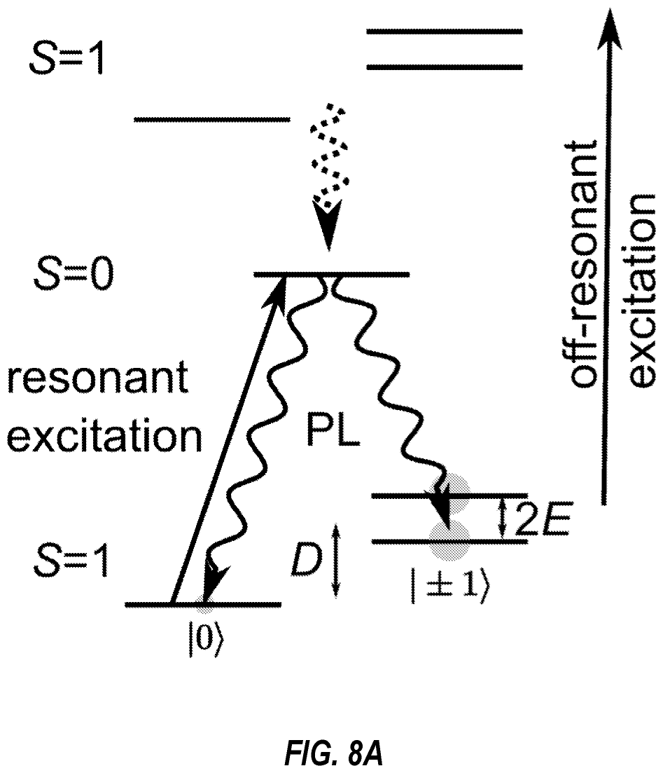

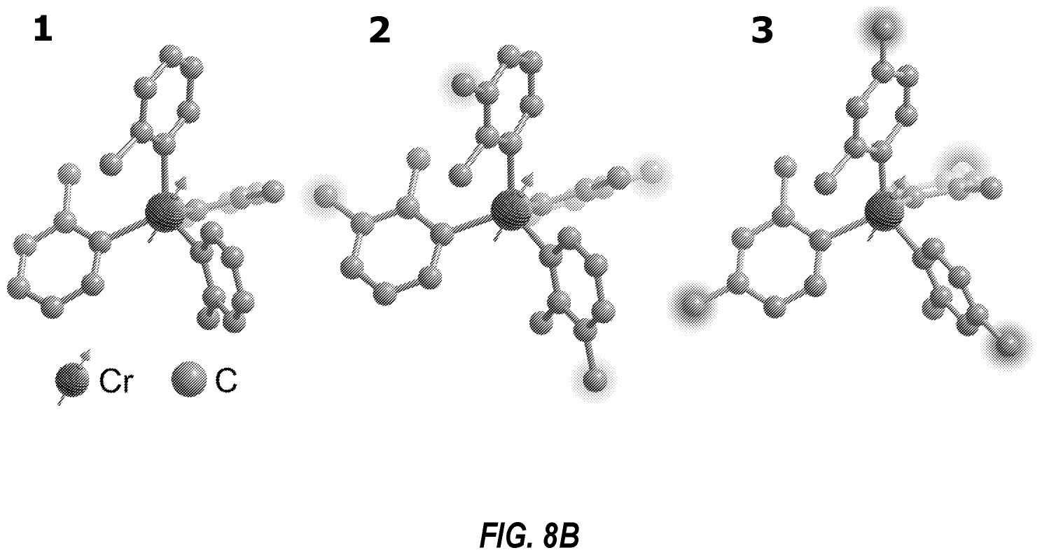

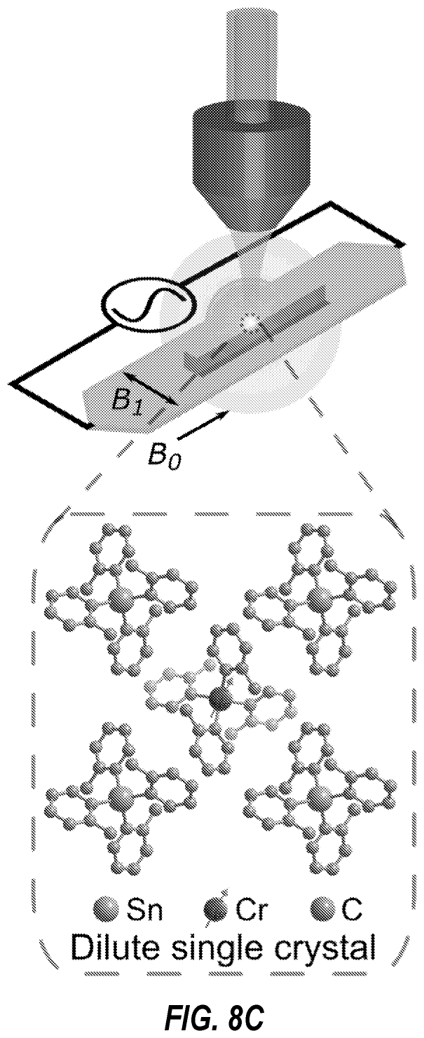

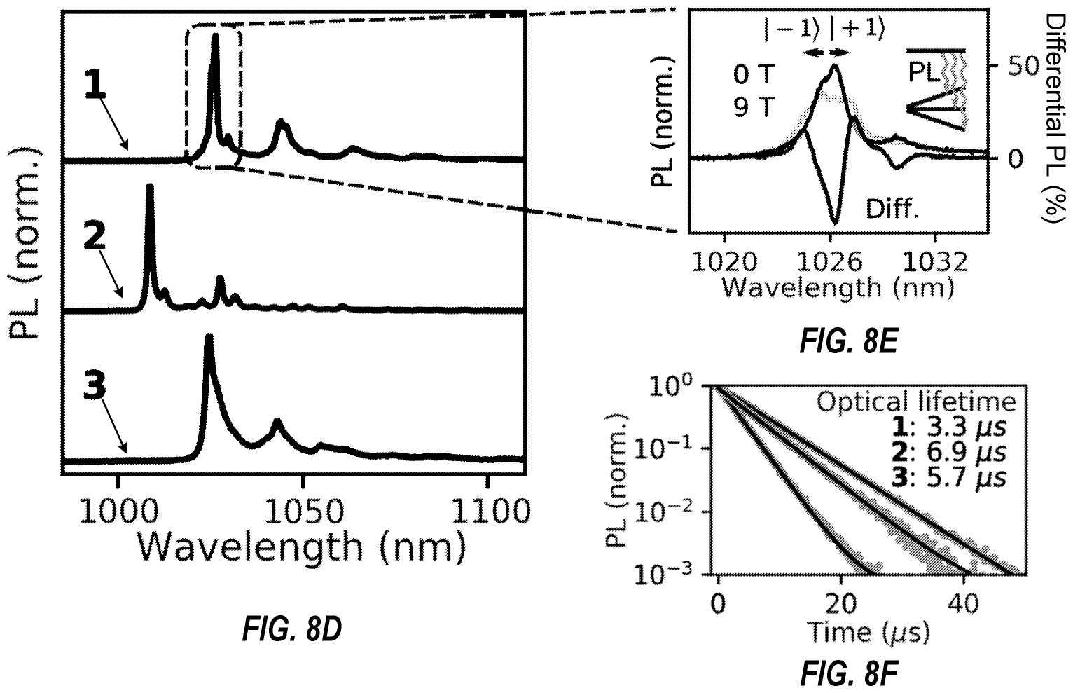

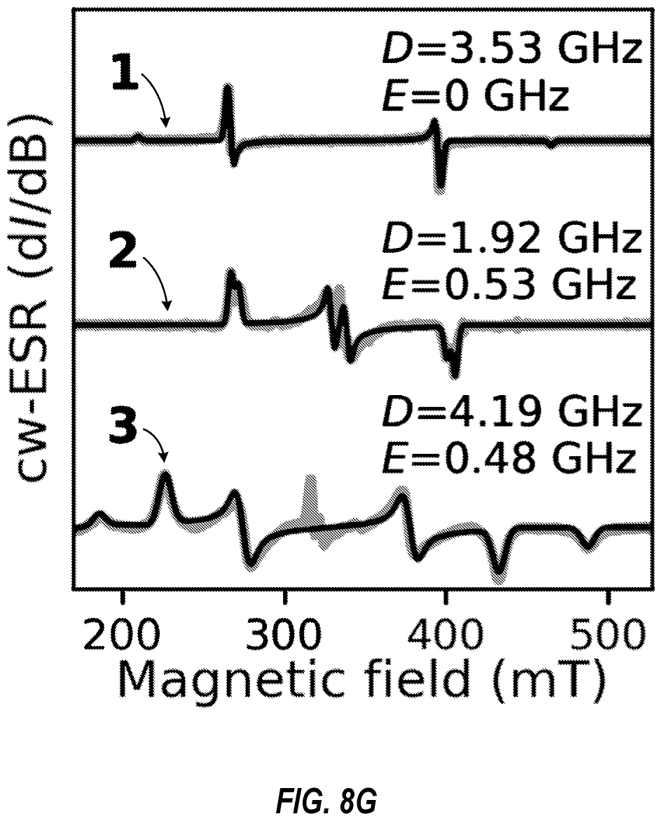

The key requirements for such an optically addressable molecular spin qubit are: (i) a ground-state spin which can be coherently manipulated, and (ii) a spin-selective optical process to initialize and read out the spin. To achieve these functionalities, we selected a chromium ion (Cr⁴⁺) coordinated by strong-field (aryl) ligands in a high-symmetry configuration, which gives rise to the energy-level structure shown in FIG. 8A. The d² electronic configuration of Cr⁴⁺ in a pseudo-tetrahedral environment produces a spin-triplet (S=1) ground state with a small ground-state zero-field splitting, characterized by the parameters D and E, allowing for spin manipulation at readily available microwave frequencies.

A strong ligand-field environment ensures that the lowest lying electronic excited state is a spin-singlet (i.e., S=0). This configuration leads to narrow optical transitions between the S=1 ground state and the S=0 excited state, which when combined with the ground-state zero-field splitting, enables optical spin readout and initialization (i.e., spin polarization) through spin-selective resonant excitation. First, optical readout of the ground-state spin is possible since a probed spin sublevel e.g., |0 [symbol] in FIG. 8A), will give rise to more photoluminescence (PL) than the other spin sublevels (e.g., |±1 [symbol] in FIG. 8A). Second, optical polarization of the ground-state spin results when selective excitation, combined with spontaneous emission, transfers population from the probed to the other spin sublevels. This is referred to as optical pumping or hole burning. Importantly, to accumulate spin polarization over multiple excitation and emission cycles, the ground-state spin-lattice relaxation time T₁ must be much longer than the excited-state lifetime Tₒₚₜ. These components are the key ingredients we use to obtain the desired optical-spin interface.

With these criteria in mind, we synthesized the three Cr⁴⁺ compounds (FIG. 8B), which differ by the placement of a single CH₃ (methyl group) on the coordinating ligands, through solution-phase chemistry. In brief, we reacted the appropriate aryl lithium species with Cr³⁺Cl₃(THF)₃ at −78° C. which undergoes a disproportionation or auto-oxidation to the corresponding tetrahedral Cr⁴⁺R₄ (R=o-tolyl, 2,3-dimethylphenyl, 2,4-dimethylphenyl). We diluted each compound in their S=0 isostructural tin analogues to form dilute molecular crystals (labeled 1, 2, 3 in FIG. 8C), thus reducing interactions between Cr⁴⁺ centers. All experiments were performed on compounds 1-3 in an optical cryostat with microwave access (≈4-5 K at the sample mount, FIG. 8C) unless otherwise stated.

Under off-resonant excitation (785 nm), ground-state population is promoted to the first S=1 excited state, undergoes fast intersystem crossing to the S=0 state, and decays to the S=1 ground state, emitting near-infrared PL. For compounds 1-3, this emission comprises sharp zero-phonon lines (ZPLs) ranging from 1009-1025 nm (FIG. 8D), along with longer-wavelength phonon sidebands. The minor ligand modifications in compounds 1-3 also result in unique ground-state spin structure, as observed in ground state electron spin resonance (ESR) measurements (FIG. 8G), with D and E lying in the readily addressable region of <5 GHz for each compound (we take D, E>0). These features, along with optical lifetimes (3.3-6.9 μs, FIG. 8G) that are much shorter than T₁, therefore suggest that compounds 1-3 satisfy the above criteria for optically addressable molecular qubits, with synthetically tunable optical and spin properties.

To further confirm the level structure in FIG. 8A, we measured the emission of compound 1 under a high magnetic field using off-resonant excitation (FIG. 8E). Due to the S=0 excited state, the Zeeman splitting of the ground state manifests directly as a shift in the optical emission energies. This effect is clearly shown by taking the difference in PL spectra at 9 and 0 T: optical emission into the |±1 [symbol] spin sublevels shift to lower and higher energies, giving characteristic peaks on either side of the zero-field ZPL in the differential spectrum, along with a central dip (the feature at 1030 nm arises from the vibrational sideband, see supplementary materials).

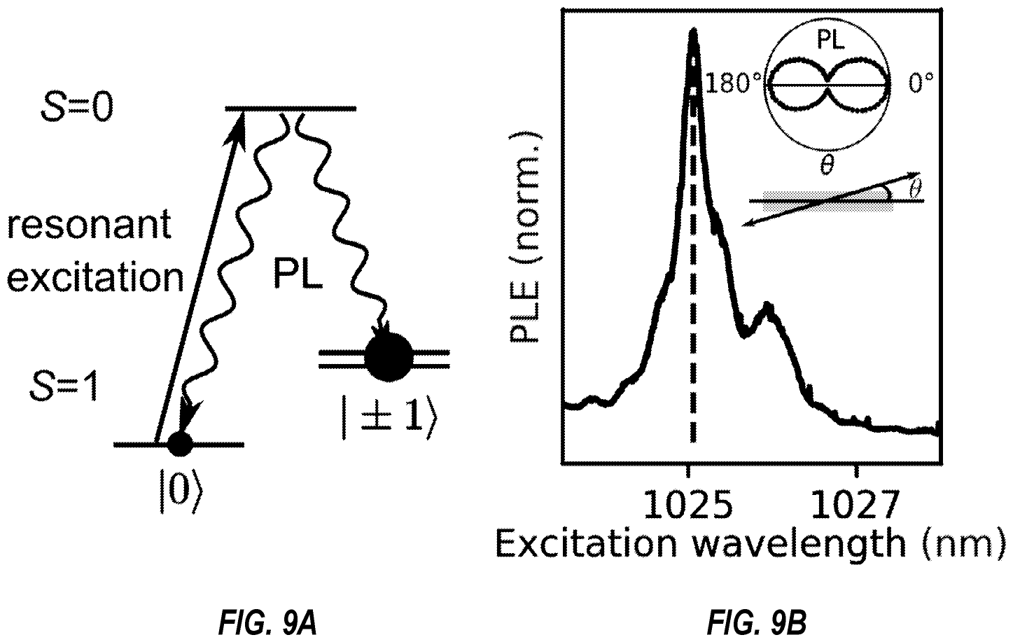

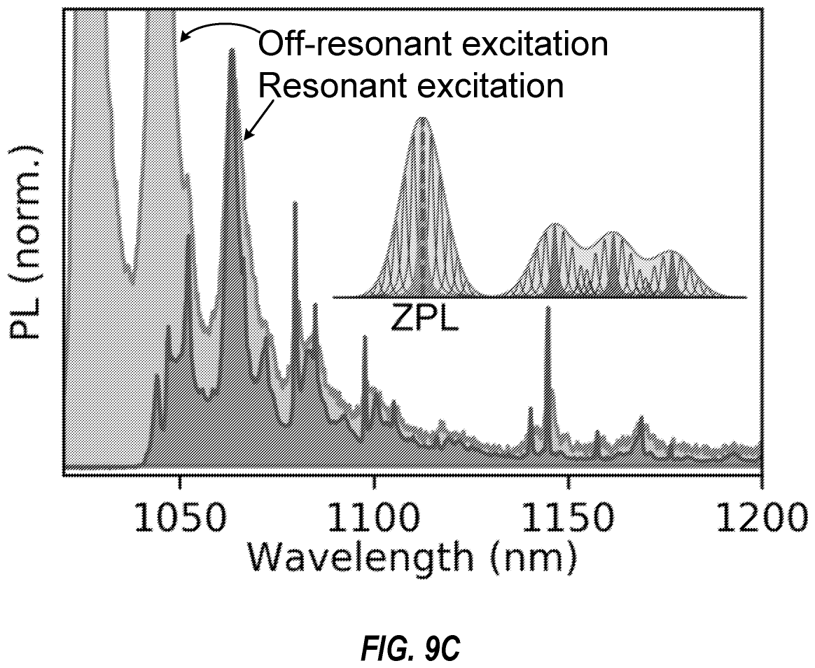

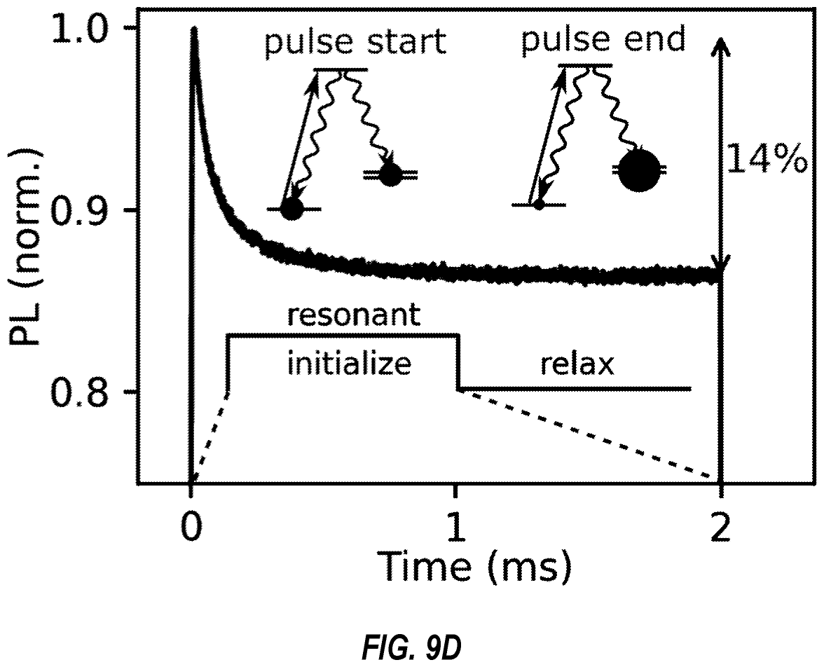

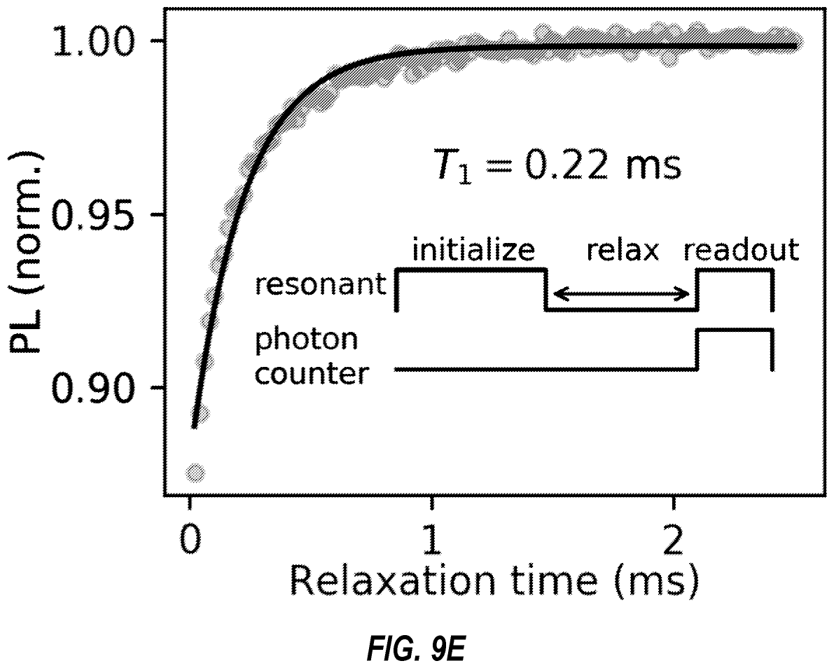

To demonstrate an optical-spin interface in these systems, we now focus on compound 1 as an illustrative example before discussing compounds 2 and 3. Using a narrow-line laser, we resonantly excite the S=1 ground state to the S=0 excited state (FIG. 9A) and collect emission into the phonon sideband to remove excitation laser scatter. First, we characterize the emission as a function of the excitation wavelength (FIG. 9B), showing a ZPL at 1025 nm: we excite at this ZPL maximum (dashed line FIG. 9B) for all following experiments. To further maximize emission, we align the excitation polarization with the optical dipole transition, which is collinear with the long axis of the crystal (FIG. 9B inset). While the optical inhomogeneous linewidth of 2150 GHz shown in FIG. 9B appears prohibitive for spin-selective excitation, as this linewidth is >>D, resonant excitation addresses a narrower subensemble of molecules from the inhomogeneous distribution (likely broadened by strain). To demonstrate that this subensemble linewidth is indeed much narrower than the inhomogeneous linewidth, we compare the phonon sidebands under resonant excitation and off-resonant excitation (FIG. 9C). The emission line narrowing under resonant excitation indicates that the ensemble ZPL indeed consists of narrower subensembles, which we use for all following spin-selective experiments.

We next measure all-optical initialization and readout of the ground-state spin using hole-burning and recovery. To initialize the spin, we apply the pulse sequence outlined in FIG. 9D consisting of a long optical pulse (2 ms), followed by a wait time to equilibrate ground-state spin populations before the next pulse. The emission during the optical pulse shows the characteristic behavior of optical spin polarization: a gradual drop in emission as population is pumped from the probed ground-state spin sublevel (the “bright” state) and into the other (“dark”) spin sublevels. The optical contrast between the start and the end of the pulse places a lower bound on the spin polarization of 14%.

Using this spin initialization, we now measure the ground-state spin-lattice relaxation time, T₁ by performing the two-pulse experiment outlined in FIG. 9E. This sequence consists of an initialization pulse (300 μs), a variable relaxation time and a readout pulse (20 μs). The initialization pulse transfers population to the ‘dark’ spin sublevels. As ground-state spin population relaxes back to the ‘bright’ sublevel, the emission increases. Measuring this emission at variable relaxation times yields T₁=0.22(1) ms. Since T₁ is significantly longer than the optical lifetime (Tₒₚₜ=3.3 μs, FIG. 8F), this confirms that many optical cycles can be used to accumulate ground-state spin polarization.

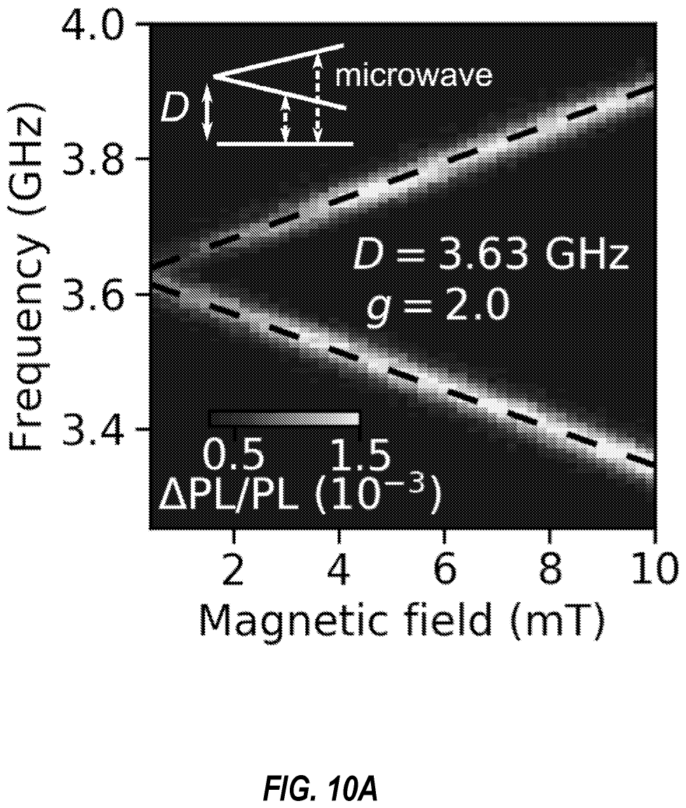

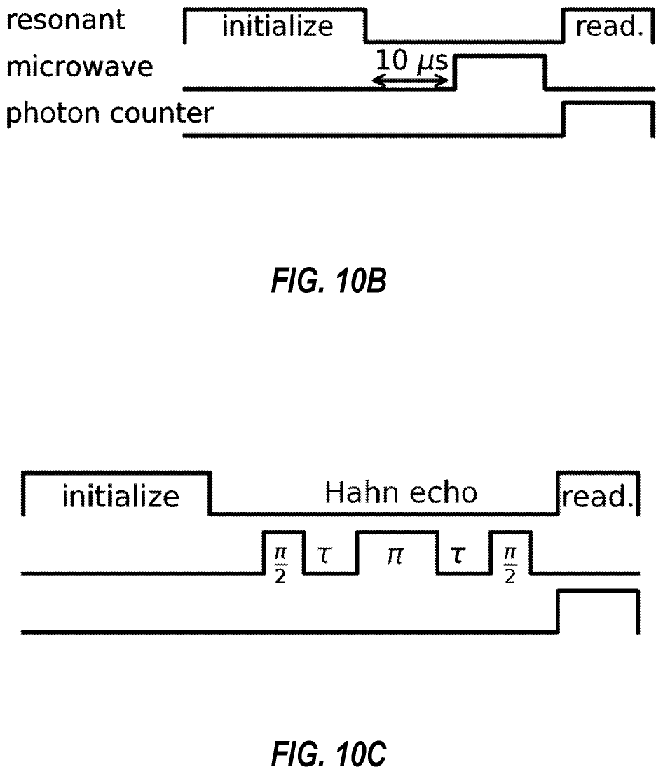

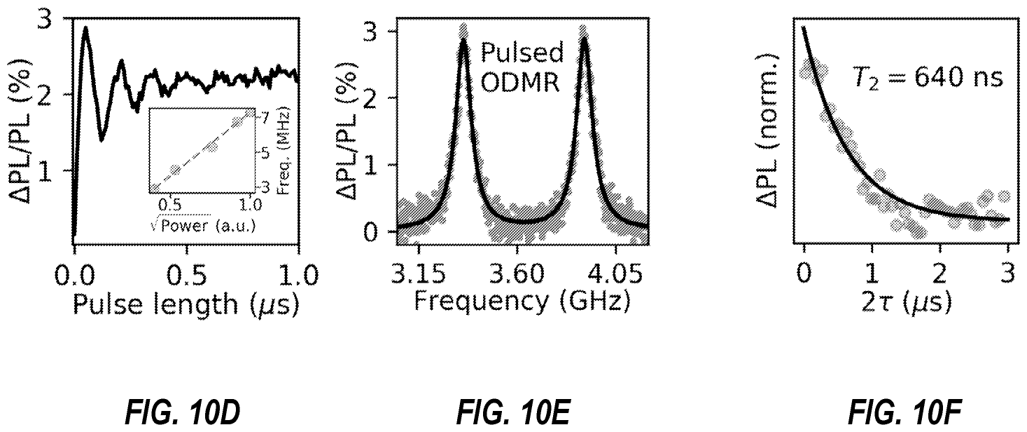

We next manipulate the ground-state spin of compound 1 using a microwave field. First, using continuous wave (cw) optical excitation, we place a subensemble of spins in the dark state and monitor changes in emission (ΔPL) as we sweep the microwave frequency. When this microwave frequency matches the spin sublevel splitting, the dark and bright sublevels are mixed, resulting in increased PL. FIG. 10A shows this optically detected magnetic resonance (ODMR) as a function of both the microwave frequency and an external magnetic field applied along the long axis of the crystal. The zero-field cw-ODMR spectrum provides D=3.63 GHz, while the Zeeman splitting yields a g-factor of 2.0, in agreement with the ESR measurements (FIG. 8G).

To demonstrate coherent control over the ground-state spin, we drive Rabi oscillations (FIG. 10D) using the pulsed ODMR sequence outlined in FIG. 10B. This sequence consists of an optical initialization pulse, a wait time, a variable length microwave pulse, and an optical readout pulse. The inset shows the expected square-root dependence of the Rabi frequency on the applied microwave power. Next, using a π-pulse calibrated from FIG. 10D, we perform pulsed ODMR at a fixed magnetic field, B₀=10 mT, while varying the microwave frequency (FIG. 10E). Finally, by replacing the single microwave pulse in FIG. 10B with a Hahn-echo sequence (FIG. 10C), we measure the spin coherence time T₂=640(60) ns (FIG. 10F, B₀=2 mT). The final π/2-pulse in the sequence projects the coherences onto spin populations for optical readout. Importantly, in these pulsed ODMR experiments, the wait time (10 μs˜3Tₒₚₜ) between initialization and microwave manipulation ensures population is in the ground state prior to coherent control. This wait time, along with the above agreement between the ODMR and ESR spin parameters, verifies that we coherently control the ground-state spin. Furthermore, the measured T₂, likely limited by the surrounding hydrogen nuclear spins, is comparable to other organometallic systems in nuclear spin-rich environments. Thus, with compound 1, we demonstrate optical initialization, microwave coherent control and optical readout of the ground-state spin in a molecular qubit.

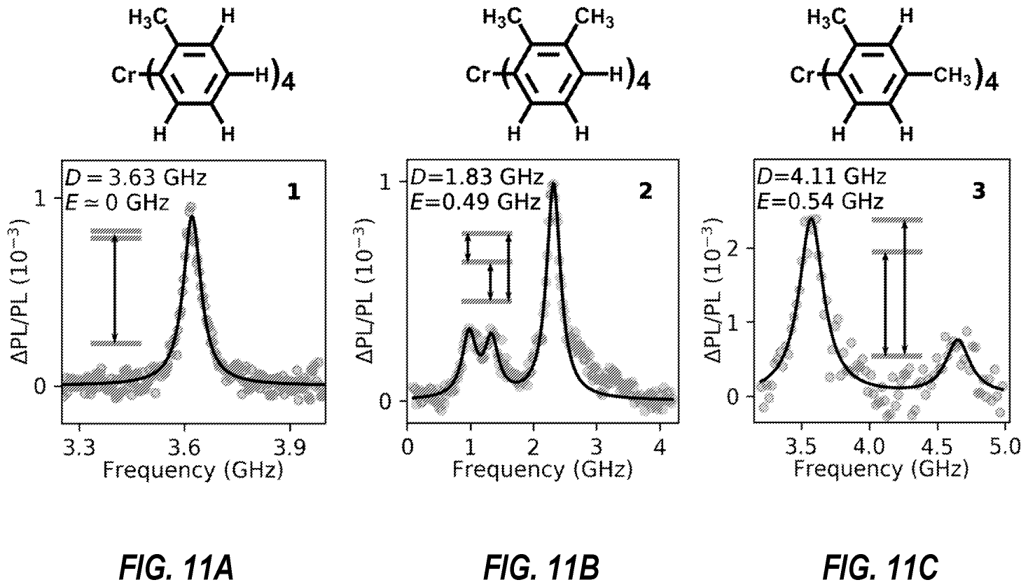

Having demonstrated an optical-spin interface and coherent spin control for compound 1, we now highlight how this functionality can be translated to a much broader class of molecules. In FIG. 11, we show robust optical initialization, microwave spin manipulation and optical readout of compounds 2 and 3 through cw-ODMR. As captured by the simulations, the variable peak intensities arise from ESR selection rules. These results therefore demonstrate engineered optical-spin interfaces in a bottom-up system with synthetic control over magnetic, electronic, and physical structure. Chemical design provides an immediate pathway to enhance such systems. For example, chemical replacement of the hydrogen nuclei (FIG. 11A) around the metal center in compound 1 through deuteration should significantly enhance the electronic spin coherence. Furthermore, the generation of a significant E in compounds 2 and 3 exemplifies the ability to engineer noise-insensitive (i.e., clock-like) transitions by reducing symmetry in molecular architectures. This work demonstrates that bottom-up design may be harnessed to create a range of quantum systems, such as scalable arrays of qubits patterned on surfaces, with variable optical and microwave resonances for single-spin addressability. Alternatively, by deterministically placing nuclear spins around the metal center, tailor-made, long-lived registers with an optical interface could be created. Finally, the portability and nanometer-scale of molecular qubits holds promise for their integration with diverse systems ranging from optical cavities for quantum optical networking to biological macromolecules for nanoscale sensing. These results open pathways to design and create quantum technologies from the bottom-up.

General Synthetic Considerations

All compounds were manipulated and handled under a dinitrogen atmosphere in an MBraun Unilab Pro glovebox. All glassware was either oven-dried at 150° C. for at least four hours or flame-dried prior to use. Diethylether (Et₂O), n-hexane (Hex), tetrahydrofuran (THF), and toluene (Tol), were degassed by argon sparging and dried using a commercial solvent purification system (Pure Process Technology) and stored over 4 Å sieves for a minimum of one day. Prior to use, the following chemicals were deoxygenated and dried as specified. Hexamethyldisiloxane (HMDSO, Sigma Aldrich) was dried over calcium hydride, distilled, deoxygenated by three successive freeze-pump-thaw cycles, and stored over 4 Å sieves. 2-Bromotoluene (Sigma Aldrich), 1-Bromo-2,3-dimethylbenzene (Sigma Aldrich), and 1-Bromo-2,3-dimethylbenzene (Sigma Aldrich) were deoxygenated by three successive freeze-pump-thaw cycles and stored over 4 Å sieves. Celite® 545 (celite, Sigma Aldrich) was dried at 250° C. under vacuum for 2 days. Methylene chloride (DCM, Fisher Scientific), n-butyllithium (nBuLi, 2.5 M in Hex, Sigma Aldrich), tin tetrachloride (Alfa Aesar) and deuterated chloroform (CDCl₃, Cambridge Isotopes) were used as received. CrCl₃(THF)₃, Cr(o-tolyl)₄ (1-Cr), Sn(o-tolyl)₄ (1-Sn), and Sn(2,4-dimethylphenyl)₄ (3-Sn) were prepared according to procedures known in the art. However, the crystal structure of 1-Cr has not been reported and hence is reported here. For 1-Sn and 3-Sn, the Grignard reagents, ArMgBr, where Ar=o-tolyl and 2,4=dimethylphenyl, were prepared by reacting the appropriate aryl bromide with magnesium turnings in either Et₂O or THF at ˜0.5 M concentration.

Synthesis and Crystal Growth

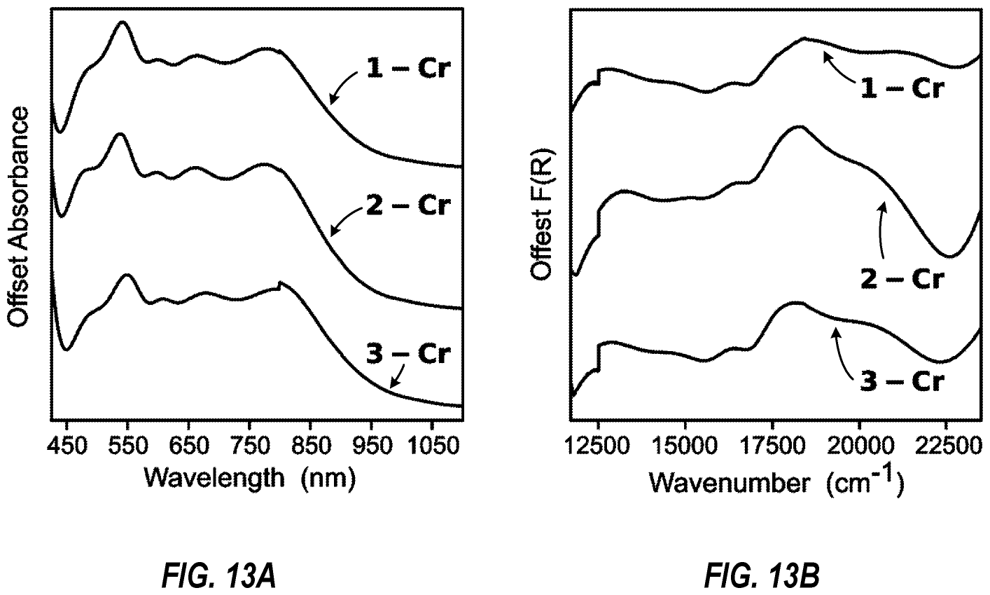

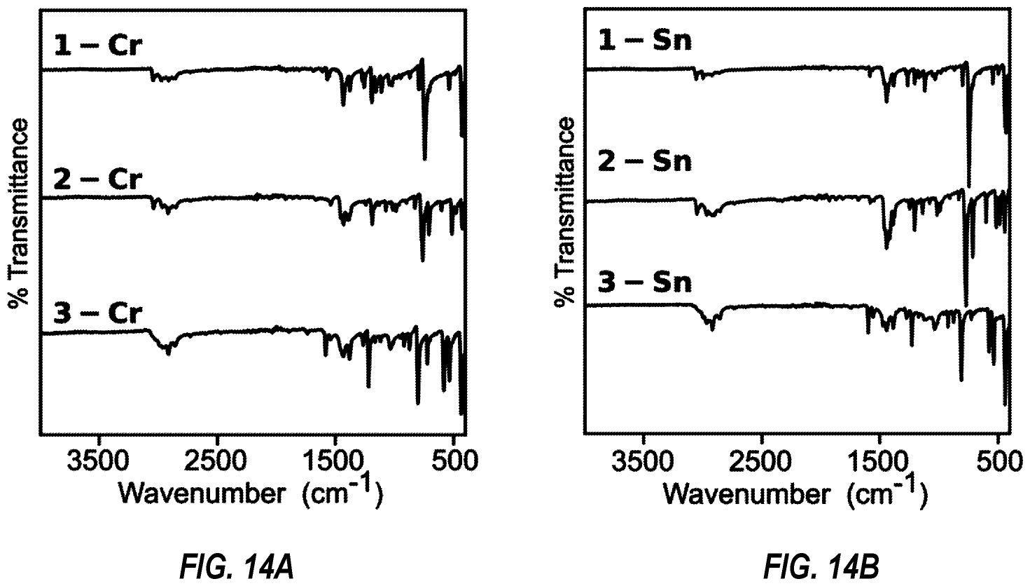

Cr(2,3-dimethylphenyl)₄ (2-Cr): In an N₂ atmosphere, 1.50 g (8.06 mmol) of 1-Bromo-2,3-dimethylbenzene was added to 10 mL of Et₂O. The solution was cooled to −78° C. and 3.4 mL of nBuLi (8.5 mmol) was added dropwise to the cold solution. The solution was stirred at −78° C. for 20 minutes, removed from the cold bath and stirred at room temperature for 1.5 hours during which time the solution was light yellow. Volatiles were removed under vacuum to obtain a white powder of crude L₁(2,3-diMe-C₆H₃). The solid was washed Hex (2×10 mL) and dried under vacuum to obtain a white powder (typical yield: 730-820 mg, 80 90%) of sufficient purity for subsequent reactions. 500 mg (5.1 mmol) L₁(2,3-diMe-C₆H₃) was added to 5 mL of Et₂O to form a light yellow solution which was cooled to −78° C. After 10 minutes, this solution was added dropwise over ˜5 minutes to a cooled suspension of CrCl₃(THF)₃ (472 mg, 1.26 mmol) in 10 mL of Et₂O at −78° C., during which time the solution turned deep purple. The solution was stirred in the dark and gradually warmed to room temperature over 2 hours. At this time, the solution retained the deep purple color and a light blue-gray precipitate had formed. The volatiles were then removed under vacuum to obtain a dark brown residue. The residue was triturated with HMDSO (20 mL) and then washed with Hex (˜40 mL). Each wash was separately isolated, filtered through a pad of celite and the solvent was removed under vacuum. The remaining purple solid was dissolved in 5-10 mL of Et₂O. 10 mL of HMDSO was added to the resulting Et₂O solution which was then filtered through a pad of celite and the solvent was removed under vacuum. Each fraction (HDMSO, Hex and Et₂O) was subsequently washed with 1:1 mixture of HMDSO:Hex and filtered through a pad of celite. Occasionally, purple solid remained on the celite pad, in which case this additional material was dissolved in Hex and filtered. This process was repeated for each fraction until the filtered solution was deep purple. (Note: the brown impurity is challenging to remove. Successive cycles of extraction into HMDSO or Hex, filtering through celite and removal of solvent under vacuum may be required to isolate the target, royal purple Cr⁴⁺ compound.) The combined fractions were then dissolved in Hex, concentrated under vacuum and stored at −35° C. Purple crystals suitable for x-ray diffraction were isolated after a few hours. To isolate the majority of the product, the crystallization continued for three or four days (typical yields: 5-15% based on the Cr³⁺ precursor where the maximum yield for this reaction is 50%). UV-Vis-NIR (Et₂₀), λₘₐₓ (ε, M⁻¹ cm⁻¹): 483 (shoulder, 1055), 538 (1330), 597 (1020), 662 (1060), 773 (1055), see FIG. 13. IR: 3040 (m), 2964 (w), 2917 (m), 2851 (w), 2727 (w), 1670 (w), 1565 (w), 1569 (w), 1537 (w), 1461 (m, sh), 1453 (m), 1429 (m), 1395 (m), 1385 (m, sh), 1383 (m), 1241 (w) 1185 (st), 1169 (st), 1130 (m), 1070 (w), 1011 (m), 984 (w), 898 (w), 823 (w), 767 (sh), 758 (vs), 599 (m), 511 (m), 480 (m), 422 (m), see FIG. 14.

Cr(2,4-dimethylphenyl)₄ (3-Cr): In an N₂ atmosphere, 1.50 g (8.06 mmol) of 1-Bromo-2,4-dimethylbenzene was added to 10 mL of Et₂O. The solution was cooled to −78° C. and 3.4 mL of nBuLi (8.5 mmol) was added dropwise to the cold solution. The solution was stirred at −78° C. for 20 minutes, removed from the cold bath and stirred at room temperature for 1.5 hours during which time the solution was light yellow. Volatiles were removed under vacuum to obtain a white powder of crude L₁(2,4-diMe-C₆H₃). The solid was washed with Hex (2×10 mL) and dried under vacuum to obtain a free-flowing white powder (typical yield: 630-775 mg, 70-85%) of sufficient purity for subsequent reactions. 500 mg (5.1 mmol) L₁(2,4-diMe-C₆H₃) was added to 5 mL of Et₂O to form a white suspension which was cooled to −78° C. After ten minutes, this suspension was added dropwise over −5 minutes to a cooled suspension of CrCl₃(THF)₃ (472 mg, 1.26 mmol) in 10 mL of Et₂O at −78° C., during which time the reaction turned deep blue. The solution was stirred in the dark and gradually warmed to room temperature over 2 hours over which time the solution turned deep bluish-purple and a brownish precipitate had formed. The volatiles were then removed under vacuum to obtain a dark brown residue. The residue was extracted with 60 mL of Hex. The dark brown mixture was filtered through a pad of celite and the solvent was removed under vacuum. The resulting residue was extracted into 40 mL of Hex, filtered through celite and the solvent was removed in vacuum. This residue was triturated with HDMSO (15 mL) and filtered through a celite pipette packed with two alternating layers of Kim Wipes and celite. This filter apparatus allowed for efficient separation of the purple product from the brown byproduct. The solvent was removed from the resulting purple solution. (Note: the brown impurity is challenging to remove, similar to 2-Cr. However, extracting into HMDSO, followed by filtration is much more useful for 3-Cr than 2-Cr. Alternatively, successive cycles of extraction into Hex, filtering through celite and removal of solvent under vacuum may be required to isolate the target royal purple Cr⁴⁺ compound.) Once the brown byproduct was largely eliminated, the Cr⁴⁺ compound was isolated via crystallization from a concentrated Hex solution at −35° C., which yielded deep purple crystals suitable for X-ray diffraction (typical yields: 5-15% based on the Cr³⁺ precursor where the maximum yield for this reaction is 50%). UV-Vis-NIR (Tol) Amax, nm (ε, M⁻¹ cm⁻¹): 500 (shoulder, 940), 549 (1220), 608 (1040), 679 (1010), 792 (1011), see FIG. 13. IR: 2984 (sh, w), 2960 (w), 2857 (w) 2912 (m), 2728 (w), 1737 (w), 1581 (m), 1537 (w), 1432 (m), 1379 (m), 1264 (w), 1217 (st), 1161 (w), 1115 (w), 1033 (m), 1015 (sh, w), 947 (w), 916 (m), 871 (m), 799 (vs), 718 (m), 581 (vs), 531 (vs), 432 (vs), see FIG. 14.

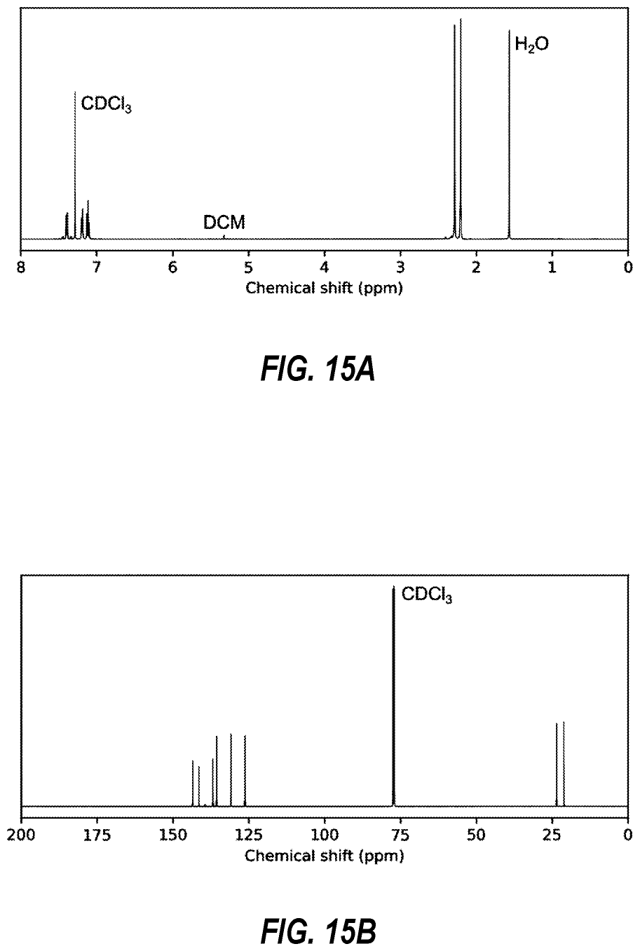

Sn(2,3-dimethylphenyl)₄(2-Sn): 2.6 g (100 mmol) of magnesium turnings were added to a 250 mL Schlenk flask and stirred for 16 hours under vacuum. THF (30 mL) was then added and the flask was fitted with an addition funnel. 5 g of 1-bromo-2,3-dimethylbenzene (27 mmol) in ˜20 mL of THF was added to the addition funnel and ˜10% of this THF/1-bromo-2,3-dimethylbenzene solution was added dropwise to the magnesium turnings over ˜1 min. The reaction was stirred until initiation occurred (solution began to boil) which took 1-90 minutes depending on how well the magnesium turnings were activated. In the cases where initiation was slow, the reaction flask was sonicated until initiation occurred. Upon initiation, the remainder of the aryl bromide solution was added dropwise to the reaction flask. The addition funnel was then replaced with a condenser and the reaction flask was put in an oil bath. The solution was heated under reflux conditions for an additional hour. The reaction was then cooled to room temperature and the mixture was filtered through a Schlenk frit into a receiving flask to isolate the 2,3-dimethylphenylmagnesiumbromide solution. SnCl₄(0.5 mL, 4.33 mmol) was added dropwise over ˜2-3 min to this stirring solution. A condenser was added to the reaction flask and the reaction was heated under reflux conditions and stirred for 16-20 hours, at which point the reaction was cooled to room temperature. ˜2-3 mL of a 1% hydrochloric acid (HCl) aqueous solution was added dropwise to the reaction mixture to quench excess 2,3-dimethylphenylmagnesiumbromide. (Note: This step can result in substantial heating if a large amount of 2,3-dimethylphenylmagnesiumbromide remains. Do not add the HCl solution rapidly to the reaction flask.) Once no heating occurred upon dropwise addition of the HCl solution to the reaction mixture, 100 mL of the 1% HCl solution was added to the reaction flask slowly. To extract the Sn(2,3-dimthylphenyl)₄ product, the mixture was transferred to a separatory funnel. The aqueous layer was washed with 3×75 mL of Et₂O. The combined organic washes were then dried with magnesium sulfate and the solvent was removed with rotary evaporation. The crude product was isolated as either a yellowish oil or a yellow solid. The resulting oil or solid was extracted into DCM (˜20-30 mL) and filtered through a pad of celite to remove any insoluble solids. Then, ˜200 mL of Hex was added to the clear solution and the solution was stored at ˜35° C. After about 24 hours, the first fraction of crystals suitable for X-ray diffraction were collected. The remaining solution was left at−35° C. to induce further crystallization. Typical reaction yields were 450-730 mg (0.83 mmol-1.35 mmol or 17-30% yield based on the Sn precursor). Similar yields are obtained when using Et₂O as the reaction solvent or when crystallizing 2-Sn from Et₂O.¹H NMR (500 MHz, CDCl₃, 298 K): 2.18 (s, 3H, Ar—CH₃), 2.26 (s, 3H, Ar—CH₃), 7.09 (t, 1H, Ar—H), 7.17 (d, 1H, Ar—H), 7.37 (d, 1H, Ar—H). ¹³C NMR (500 MHz, CDCl₃): 21.09, 23.48, 126.16, 130.18, 135.52, 1369.79, 141.37, 143.45, see FIG. 15. IR (ATR): 3049 (w), 2966 (w), 2919 (w), 2899 (w), 2853 (w), 2731 (w), 1680 (w), 1581 (w), 1569 (w), 1548 (w), 1461 (m, sh), 1441 (st), 1412 (st), 1385 (m, sh), 1379 (m, sh), 1245 (m) 1272 (w) 1204 (st), 1171 (st), 1136 (m), 1077 (w), 1013 (m), 990 (w), 908 (w), 830 (w), 767 (vs), 712 (st), 599 (m), 513 (m), 482 (m), 445 (m), see FIG. 14.

Dilute Crystallization Conditions

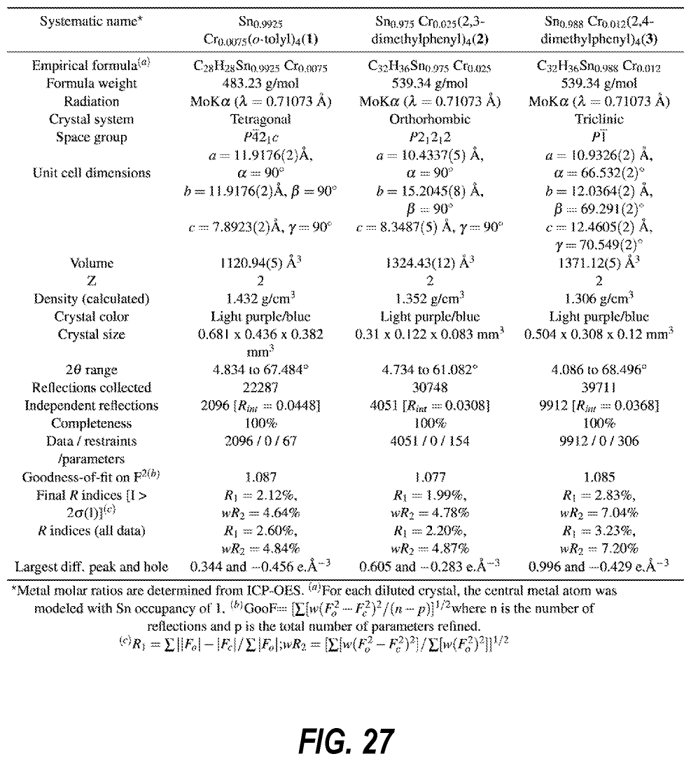

The following procedures are the general procedures to reliably produce crystals suitable for single-crystal X-ray diffraction for compounds 1-3. In each structure, the packing is dictated by the host matrix. For each compound, the Sn derivative was significantly less soluble than the corresponding Cr compound in Hex and Et₂O. For ODMR and ESR samples, the molar ratios of Cr:Sn were determined with inductively coupled plasma-optical emission spectrometry (ICP-OES). (1) 2 mg of 1-Cr and 110 mg of 1-Sn were dissolved in ˜15 mL Et₂O. The solution volume was then reduced to ˜5 mL under vacuum, layered under ˜10 mL of Hex and stored at −35° C. for 6 days, at which point light purple needle-like crystals formed. The needle-like morphology of the diluted crystal of 1 reflects its tetragonal crystal system, where the unit-cell parameters a=b ≠c (see FIG. 27), indicating that the long axis of the crystal is the unique crystallographic c-axis. The resulting Cr:Sn ratio was 0.75%. Crystals from the same batch were used for both ODMR and pulsed ESR measurements. (2) 3 mg of 2-Cr and 95 mg of 2-Sn were dissolved in ˜5 mL Tol. This solution was layered under 10 mL of Hex and stored at −35° C. for 4 days, at which point light purple crystals formed. The resulting Cr:Sn ratios in two separate batches of crystals were 2.5% for the ODMR samples and 1.1% for the ESR samples. (3) 2 mg of 3-Cr and 95 mg of 3-Sn were dissolved in ˜15 mL THF. The solution volume was then reduced to ˜5 mL under vacuum, layered under ˜10 mL of Et₂O and stored at −35° C. for 1.5 days. After 2 days, light purple plate-like crystals formed. The resulting Cr:Sn ratios in two separate batches of crystals were 1.3% for the ODMR sample and 1.1% for the ESR sample.

X-Ray Diffraction

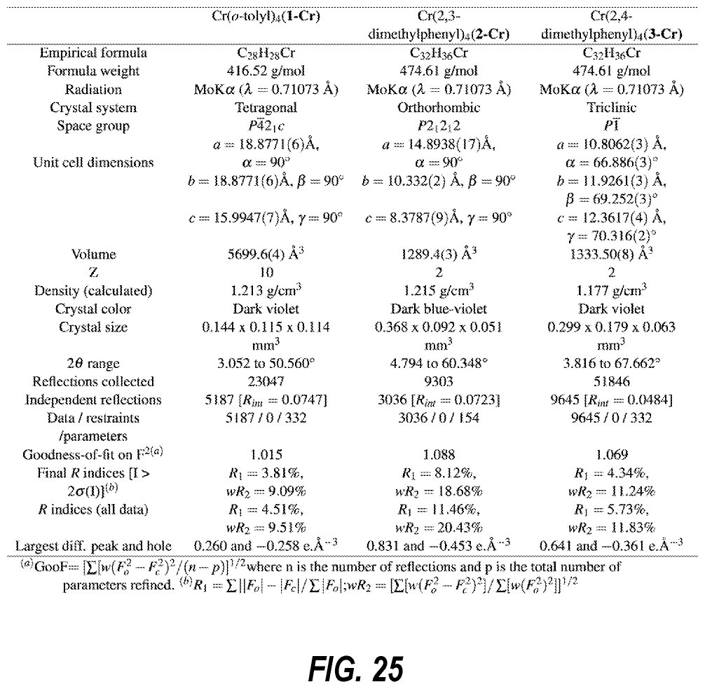

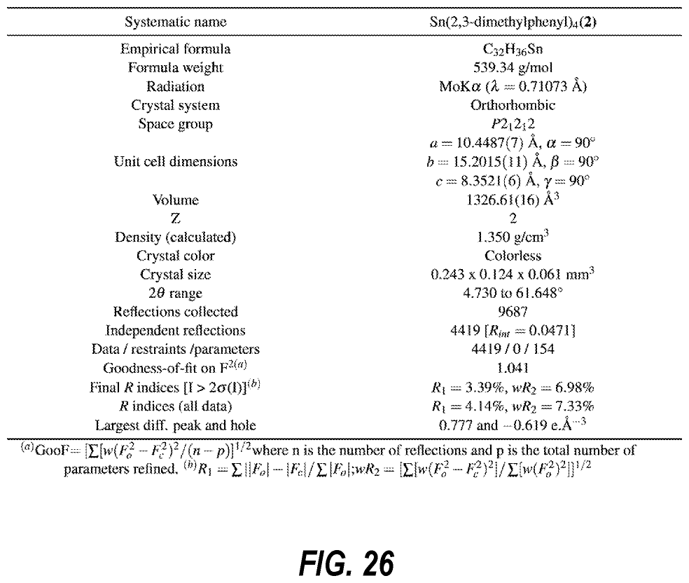

Diffraction data for 1-Cr, 2-Cr, 3-Cr, 2-Sn, 1, 2, and 3 were collected at the X-ray Crystallography Lab of the Integrated Molecular Structure Education and Research Center at Northwestern University. All crystals were coated with Paratone N oil and mounted on MiTeGen MicroMounts™ rods under a stream of N2 at 100 K. Crystallographic data for 1-Cr, 2-Sn, and 2 were collected on a Bruker KAPPA diffractometer with a MoKα IμS microfocus X-ray source with Quazar Optics, Apex II detector, and an Oxford Cryosystems Cryostream cryostat. Crystallographic data for 2-Cr, 3-Cr, 1, and 3 were collected on a Rigaku XtaLAB Synergy (Single source) with a micro-focus sealed X-ray tube PhotonJet (MoK) radiation source, HyPix CCD detector and an Oxford Cryostream cooler. Raw data were integrated using SAINT V8.30 A for 1-Cr, 2-Sn, and 2 and CrysAlisPro for 2-Cr, 3-Cr, 1, and 3. Absorption corrections were applied using SADABS V2.03 for 1-Cr, 2-Sn, and 2 and multi-scan absorption correction with the SCALE3 ABSPACK module in CrysAlisPro. The space groups of each compound were determined by examination of systematic absences, E-statistics, and successive refinement of the structure. Using the OLEX2 interface, the structures were solved with intrinsic phasing or direct methods and further refined using least squares minimization with SHELXT or SHELXL. Thermal parameters for all non-hydrogen atoms were refined anisotropically. All hydrogen atoms were fixed at ideal positions, refined using a riding model for all structures, and refined using isotropic displacement parameters derived from their parent atoms. Full crystallographic details of 1-Cr, 2-Cr, 3-Cr, 2-Sn, 1, 2, and 3 are listed in FIGS. 25-27.

Physical Characterization

Infrared spectra were recorded on pure powder samples of 1-Cr, 2-Cr, 3-Cr, 1-Sn, 2-Sn and 3-Sn at room temperature on a Bruker Alpha II FTIR spectrometer with an attenuated total reflectance accessory. FTIR spectra for 1-Cr, 2-Cr and 3-Cr were collected in a dinitrogen atmosphere. The solution-phase ¹HNMR and ¹³C NMR spectra for 2-Sn were collected on Bruker Avance III HD spectrometer with a TXO Prodigy probe and a Bruker Avance III 500 MHz spectrometer with a DCH CryoProbe, respectively. Small satellite peaks in the¹³C NMR spectrum result from incomplete decoupling of ¹³C and ¹H nuclei. UV-Vis-NIR and diffuse reflectance spectra were collected on a Varian Cary 5000 spectrometer at room temperature in Tol, Et₂O or Hex for the solutions (no appreciable changes were observed between solvents) or diluted in KBr for solid-state measurements. Extinction coefficients (E) listed above were calculated from a linear fit of the absorbance values at Amax versus concentration using four concentrations for each compound. Abbreviations above are denoted as follows: for IR, weak (w), moderate (m), strong (st), very strong (vs), shoulder (sh); for NMR, singlet (s), doublet (d), triplet (t). ICP-OES measurements were collected with a Thermo iCAP 7600 instrument.

Pulsed Optical and Microwave Measurements

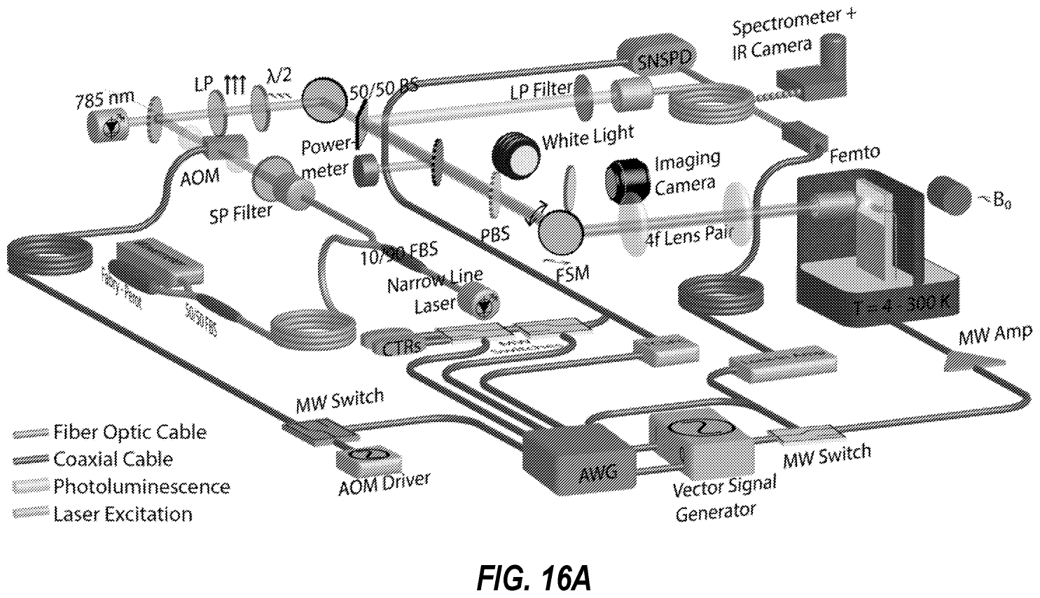

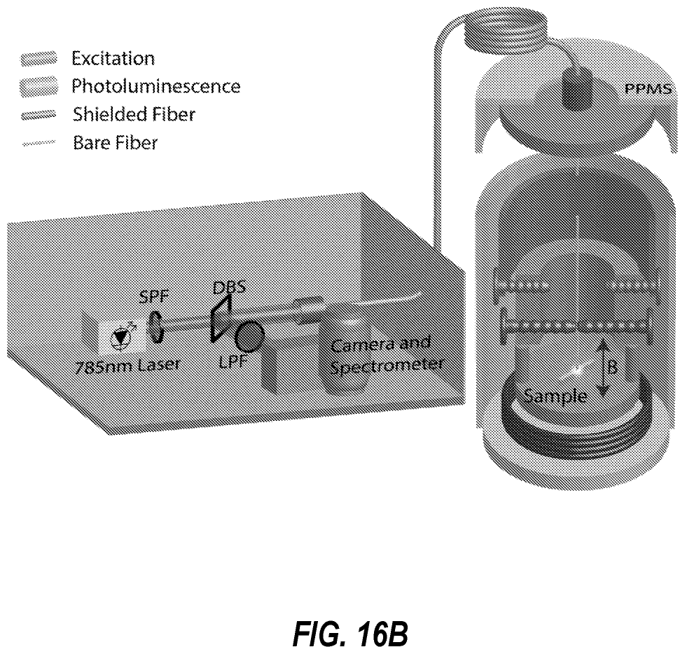

For all experiments described above, we used the setup outlined in FIG. 16A. The dilute crystals, with linear dimensions ˜0.1 −1 mm, are mounted on a coplanar waveguide (CPW) for microwave delivery and encapsulated with a thin layer of epoxy (Illumabond, UV curing epoxy, 60-7180RCL13) to prevent air exposure while loading into the cryostat. This CPW is then mounted inside a closed-cycle optical cryostat with microwave access (Montana Instruments, Cryostation s100) on an XYZ positioner stack (Attocube: 2×ANPx101/RES/LT, 1 ×ANPz102/RES/LT), which allows translation of the sample.

Off-resonant (785 nm) excitation is provided by a laser diode (Thorlabs, FPL785S-250). For resonant excitation, we use a narrow-line tunable laser (Sacher, LION). Shortpass (SP) filters are used to clean-up the excitation beams. To accurately determine the resonant laser wavelength and ensure its single-mode operation, we split off part of the resonant beam using fiber beamsplitters (FBSs) and send these portions to a wavemeter (Bristol, 621A) and a scanning Fabry-Perot interferometer, respectively (Thorlabs, SA200-8B). For pulsed optical experiments, the resonant laser is modulated using an acousto-optic modulator (AOM, Gooch & Housego, 15200-.93) driven by a radio frequency (RF) AOM driver (Gooch & Housego, R21200-1DS). This driver is controlled by an arbitrary waveform generator (AWG, Tektronix, AWG5014C) which provides the master clock for the experiments.

A linear polarizer (LP, Thorlabs, LPNIR100-MP2) in conjunction with a motorized half-wave plate (HWP, Thorlabs, AHWP10M-980 and PRM1Z8) are used to control the optical polarization. The excitation beam passes through a broadband 50:50 beamsplitter (BS, Thorlabs, BSW29R) which we use to separate excitation and collection paths. A power meter (Thorlabs, PM100D) combined with a flip mirror allows measurement of the incoming optical power. The imaging system, consisting of a white-light source, a pellicle beam splitter (PBS) which can be flipped in and out of the beam, and an imaging camera allows imaging of the sample surface. A fast steering mirror (FSM, Newport, FSM-300) in combination with the 4f lens pair allows fast scanning of the beam around the sample.

The beam is focused onto the sample using an objective (Olympus, LCPLN100XIR, NA=0.85) mounted inside the cryostat. (Based on the excitation volume and the Cr⁴⁺ concentration determined above, we estimate there are ˜10⁷ Cr⁴⁺ molecules in the laser spot for 1.) The PL is collected by the same objective, reflects off the 50:50 BS, and the laser scatter is removed using a longpass (LP) filter. The PL is coupled either into a single-mode fiber to be detected with a superconducting nanowire single photon detector (SNSPD, Quantum Opus, Opus One), or into a multi-mode optical fiber. The multi-mode path can be sent either to an InGaAs photoreceiver (Femto, OE-200-IN1) which is used for the cw-ODMR experiments, or to a spectrometer (Acton, SpectraPro 2500i) combined with a CCD (Princeton Instruments, Pylon-IR), which is used for spectral measurements. For the lifetime (see FIG. 8F) and hole-burning experiments (see FIG. 9D), the counts from the SNSPD are sent to a time tagger (TCSPC, Swabian Instruments, Time Tagger 20), which is triggered by the AWG, which also triggers the optical pulse from the AOM. For the experiments involving gated readout (i.e., FIGS. 9E and 10D-10F) the SNSPD output is amplified to a transistor-transistor logic (TTL) level using a pulse converter (Pulse Research Lab, PRL-350TTL). These pulses are gated by switches (Minicircuits, ZASWA-2-50DRA+) that are controlled by the AWG, and collected using counters in a data acquisition card (CTRs, DAQ6363, National Instruments).

Microwave (MW) signals are generated by a signal generator (PXIe-5652, National Instruments), and modulated with an IQ modulator (Polyphase, AM0350A) or a microwave switch (Minicircuits, ZASWA-2-50DR) before being amplified (MW Amp, Amplifier Research, 25S1G4A or Minicircuits, ZHL-16 W-43-S+, ZHL-20 W-13SW+ or ZVE-3 W-83+) and sent to the sample. We monitor the transmitted microwave power using a directional coupler and Schottky diode (Herotek, DZM185AB). For cw-ODMR experiments, microwaves are square-wave modulated at 317 Hz using the switch and the PL signal from the Femto detector is measured with a lock-in amplifier (Signal Recovery, 7265) at this modulation frequency. For the Rabi and pulsed ODMR experiments, the sequence in FIG. 10B is run with and without the microwave pulse in direct succession. The PL from the microwave-off sequence is then subtracted from the microwave-on sequence for baseline correction. For the Hahn echo experiments, we use a (π/2)ₓ-τ-(π)_{y}-τ-(π/2)_{±X} sequence, in which we phase-cycle the final microwave pulse, and take the difference in PL from the (π/2)_{±X}sequences. A static magnetic field B₀ is applied to the sample using a permanent magnet outside the cryostat. This magnet is mounted on a motorized linear translation stage (Zaber, X-LSQ150A) and the field at the sample calibrated using a Gaussmeter.

High Magnetic Field Experiments

High-field measurements up to B=9 T (see FIG. 8E) were performed in a cryostat with an integrated superconducting magnet (Quantum Design Physical Property Measurement System, PPMS—see FIG. 16B). The sample was cooled to a temperature of 10 K through helium exchange gas. To provide optical access to the sample, we use an optical fiber (Thorlabs, FP400ERT) mounted in a custom-built probe. The sample end of the probe mounts to the base of the PPMS through a sample-mount puck. The (unconnectorized) end of the optical fiber at the sample is mounted directly on the sample to provide excitation and PL collection, and is clamped in place. A custom-made vacuum compatible fiber feedthrough connects this fiber to excitation and collection optics outside of the cryostat which consist of a free-space optical breadboard setup. We illuminate the sample using an off-resonant 785 nm diode laser (Thorlabs, FPL785S-250) which is spectrally filtered, passes through a dichroic mirror (Thorlabs, DMSP1000R) and is then coupled into the optical fiber connected to the sample. The PL from the sample is collected using the same fiber, spectrally separated from the excitation light using the dichroic mirror and a longpass filter (Thorlabs, FELH1000) and sent to a spectrometer (Princeton Instruments, SP2500) equipped with a liquid nitrogen cooled InGaAs CCD (Princeton Instruments, OMA V:1024-2.2). For the optical Zeeman experiments in FIG. 8E, we used a 600 grooves/mm grating. PL spectra as a function of field were measured by ramping the magnetic field from 0->9 T, while simultaneously acquiring spectra. Spectra are then averaged over a window of ±100 mT.

Continuous-Wave Electron Spin Resonance (ESR)

Crystalline samples of compounds 1-3 were prepared as outlined above and ground to form microcrystalline powders. Samples were loaded into 4-mm outer diameter quartz ESR tubes under a dinitrogen atmosphere, restrained with eicosane and flame sealed under vacuum. Prior to measurements, samples were primarily stored in the dark to prevent potential degradation. Continuous-wave (cw) ESR spectra were collected at the California Institute of Technology facility using a Bruker EMX X-band spectrometer and a liquid nitrogen immersion dewar. All measurements were performed at 77 K. Spectra were acquired with the Bruker Win-ESR software suite.

Pulsed Electron Spin Resonance

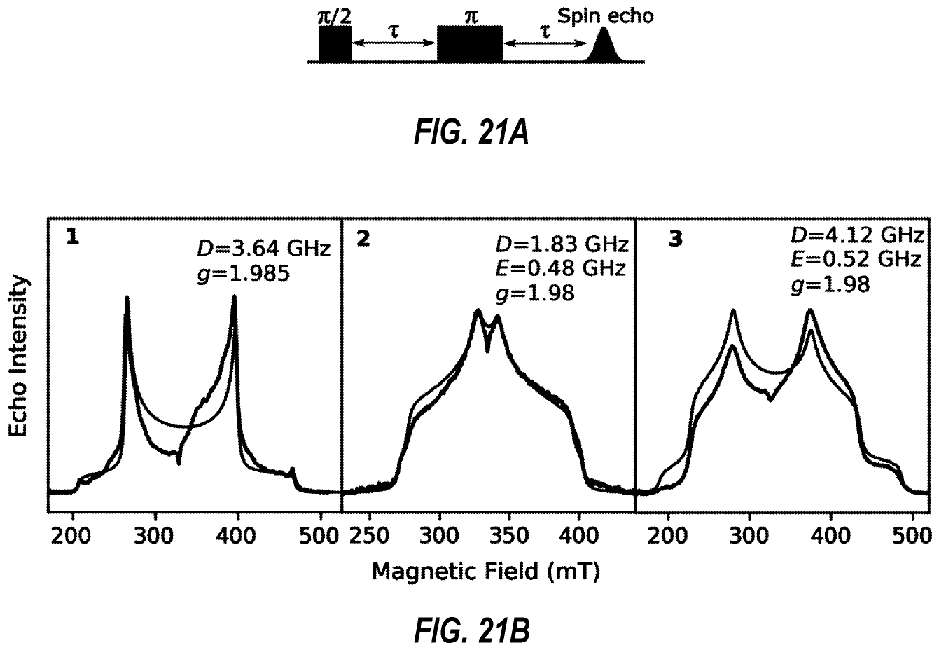

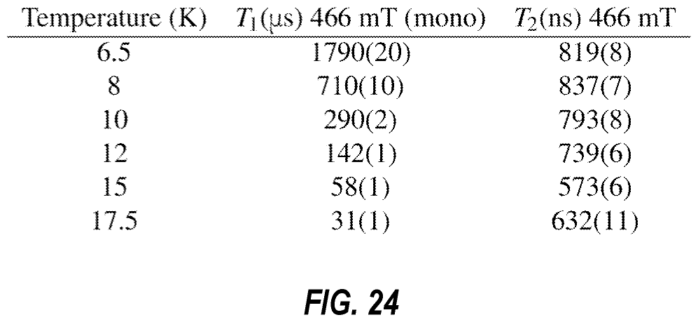

In addition to the pulsed ODMR experiments described above, we also performed pulsed ESR to further characterize the ground state spin. Pulsed-ESR data were collected at the California Institute of Technology facility using a Bruker ELEXSYS-E580 pulse ESR spectrometer equipped with a Bruker MS-5 resonator and a 1 kW TWT amplifier (Applied Systems Engineering). Temperature control was achieved using an Oxford Instruments CF395 LHe flow cryostat with an Oxford Instruments Mercury integrated temperature controller. Echo-detected field swept (EDFS) spectra were collected at 5-10 K for 1-3 using a Hahn echo pulse sequence with a fixed τ value while sweeping the magnetic field (see FIG. 21). We note that distortions to the lineshape in these spectra occur due to electron spin echo envelope modulation (ESEEM) effects from the coupling of the electronic spin of Cr⁴⁺ to nearby hydrogen nuclei. These distortions are more pronounced for 1 due to the high microwave power used. By reducing the microwave power, these effects are mitigated for 2 and 3. Spin-lattice (T₁) and spin-spin (T₂) relaxation times were measured at 466 mT where the magnetic field is approximately parallel to the principal axis of the zero-field splitting tensor (see FIG. 21B). For the T₁ measurements, we used an inversion recovery sequence consisting of a π pulse followed by a variable delay time, T, and a Hahn echo detection sequence (π-T-π/2-τ-π-τ-echo). The data were fit using a mono exponential function to directly compare to the all-optical T₁ measurements (see FIG. 9E). We note that the low temperature inversion recovery curves show slight deviations from mono-exponential behavior, likely a result of spectral diffusion. T2 times were measured using the Hahn echo pulse sequence (π/2-τ-π-τ-echo), and fit to a monoexponential decay. All of these measurements used 8-ns π/2 pulses and 16-ns π pulses and two-step phase cycling. Measured T₁ and T₂ times are listed in FIG. 24.

CW-ESR Simulations

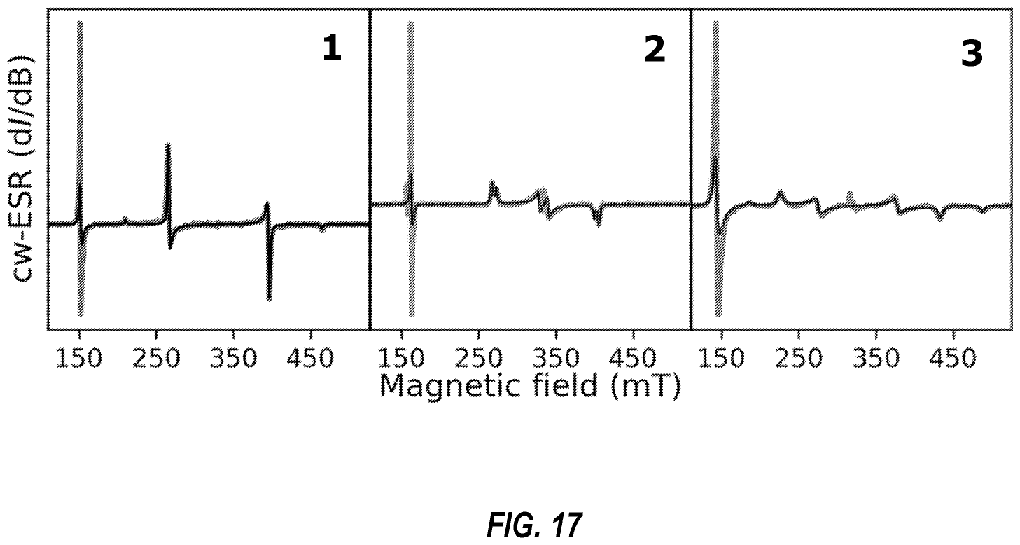

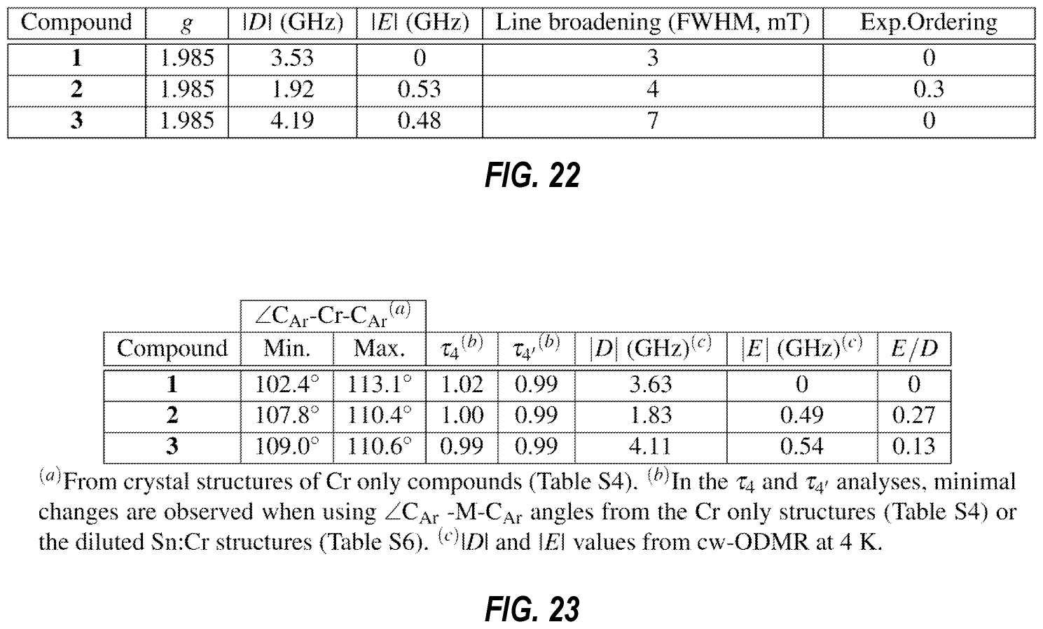

Spectral simulations in FIG. 8G were carried out with the spin Hamiltonian in Eqn. S1 using EasySpin, with a Lorentzian line broadening. We found that the peak intensities of the full-field (g ≃2) and half-field transitions (g ≃4), see FIG. 17, could not be fully captured using exclusively D strain (which selectively broadens the high-field transitions), or a fixed line broadening for all transitions (from e.g. unresolved hyperfine interactions), indicating both of these effects contribute to the line broadening. We note, however, that the spectral peak positions are sufficient to extract the ground state spin parameters, D, E and g, and are well-captured by the simulations (see FIGS. 8G and 17). In 2 and 3, we observe two features at g ≃2 and g ≃2.1, respectively which are not captured by the simulations. We assign these features to double quantum transitions between the |+1 [symbol] and |−1 [symbol] states. The same feature appears in 1, but the intensity is greatly diminished relative to the single quantum transitions. Since the feature occurs at g ≃2.1 for 3, we assign it to a double quantum transition, rather than an organic radical or a chromium based complex, as these species should produce a feature at g≲2. For 2, an additional parameter, Exp. Ordering (set as +0.3), is required to model the peak intensities. This parameter indicates a slight preferential orientation resulting from a non-uniform distribution of molecular orientations, which is likely caused by incompletely ground crystallites of 2 and may also give rise to the additional small half-field feature at ≃157 mT. Simulation parameters are given in FIG. 22.

Relationship Between Zero-Field Splitting Parameters and Crystal/Molecular Structure

The cw-ODMR spectra of 1-3 in FIG. 9 show variable ground-state spin fine structure with |D| values ranging from 1.9-4.2 GHz and |E/D| ratios from 0-0.27 (see FIG. 23). First, considering the range of |E/D| ratios for 1-3, we attribute the variation in rhombicity to the crystallographically enforced molecular symmetry. For example, the space group of the diluted crystal of 1, P-42₁c, results in a tetragonal compression along the c-axis, giving rise to non-zero D. This tetragonal compression also introduces a 4-fold rotoinversion axis colinear with the crystallographic c-axis, resulting in an S₄ point group at each metal site. From the single crystal ODMR experiment in FIG. 10A, when applying a magnetic field along the c-axis (crystal long axis) we observe a Zeeman splitting predicted for the alignment of the external field with the principal axis of the zero-field splitting tensor, D. Thus, the principal axis of D must also be colinear with the 4-fold rotoinversion axis. Since this 4-fold rotoinversion axis imposes equivalence in the ab plane that is perpendicular to the principal axis of D, E is crystallographically restricted to be zero, as we observe. Moreover, the molecules in the unit cell of 1 are related by glide planes that contain the 4-fold rotoinversion axis, such that the principal axis of D is colinear for all metal sites. As a result, we observe only a single set of transitions in the the ODMR spectra, corresponding to the transitions between the |0 [symbol] and |±1 [symbol] spin sublevels. Conversely, the space groups of 2 (P2₁2₁2) and 3 (P-1) result in C₂ and C₁ point groups, respectively. In each case, the metal centers lack 3-fold (or higher) rotation or rotoinversion axes, and thus, equivalence of the transverse plan is not crystallographically enforced. As a result, both 2 and 3 exhibit non-negligible |E|.

Now considering D, we find that |D| is not directly proportional to the deviation from ideal T_{d} symmetry (i.e. distortion in ∠C_{Ar}-Cr-C_{Ar}, from the ideal 109.5°, where C_{Ar} is the carbon atom directly bound to the Cr⁴⁺ center). We employed τ4 and τ₄, analyses to determine the deviation from T_{d} symmetry. From these analyses, we find no clear correlation between local molecular distortion and |D|. For example, the τ4 and τ₄, values are nearly identical for compounds with the largest (3) and smallest (2) |D| values, illustrating that local molecular distortions alone are not sufficient to model variations in |D|. Rather, for 1-3, various interactions, such as donation from the aryl ligands, and crystal packing effects, e.g., due to deviations in the ligand twist angles, likely influence |D| also. The different factors influencing the zero-field splittings of these compounds highlight the multiple possibilities available for modifying optically addressable molecular qubits. For example, dilution of a Cr⁴⁺ species in a lower symmetry, tin host, such as dilution of 1-Cr in 2-Sn, may give rise to a finite E despite the fact that E was crystallographically restricted to zero in 1. Thus, manipulation of host-guest interactions through solution-phase chemistry provides an additional parameter to tune ground-state spin structure. We expect that through improved theoretical and empirical understanding of the parameters influencing zero-field splitting, directed control of both D and E could be possible.

Zeeman Splitting Observed Through Photoluminescence

The optical Zeeman experiments presented above (see FIG. 8E) show the dependence of the ZPL of 1 on an applied magnetic field B, highlighting the S=0->S=1 nature of the optical transition. Since the excited state is S=0, this singlet state does not experience a Zeeman splitting, while the S=1 ground-state does. The ground-state spin Hamiltonian is

$$H = hD ( {S}_{Z}^{2} - \frac{1}{3} S ( {S \underbrace{+} 1}_{{H}_{z f s}} ) ) + hE ( {S}_{x}^{2} - {S}_{y}^{2} ) + {g {μ}_{\underbrace{B}} B \cdot S}_{{H}_{Zeeman}} , \qquad ( S1 )$$

where D, E are the zero-field splitting parameters, h the Planck constant, S=(Sₓ, S_{y}, S_{z}) is the vector of spin-1 operators, g is the electronic g-factor, μ_{B} the Bohr magneton and B the applied field, with magnitude |B|=B. The Zeeman splitting of the S=1 ground-state manifests as spectral shifts in the PL from the singlet state to the |±1 [symbol] triplet spin sublevels. Due to the inhomogeneous broadening of the ZPL, we do not resolve a complete separation of the spin sublevels at the field ranges accessible to our experiment (B≤9T). However, the Zeeman splitting can be clearly resolved in the differential PL spectra defined as

$$\frac{P L ( λ , B ) - P L ( λ , B = 0 )}{P L ( λ = {λ}_{0} , B = 0 )} , \qquad ( S2 )$$

where λ₀ is the wavelength of the peak in the zero-field PL spectrum. Since the |0 [symbol] spin sublevel does not move with the field, its associated optical transition cancels out in the differential spectrum, more clearly revealing the splitting of the |±1 [symbol] spin sublevels.

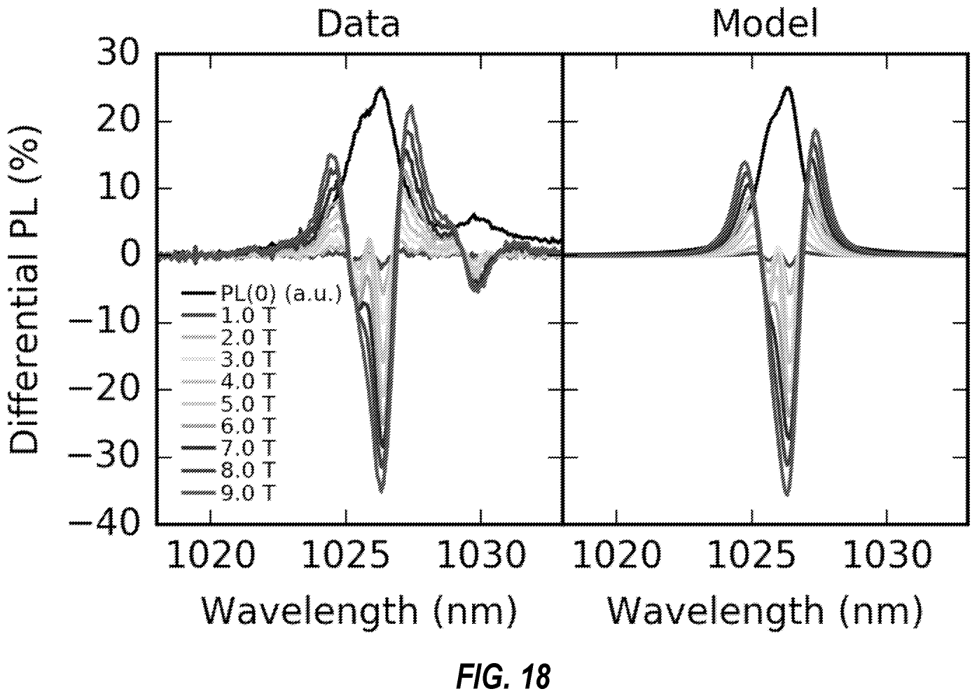

To model the changes in PL as a function of field, we take a Gaussian lineshape for each of the emission lines from the singlet excited state into each of the ground-state spin sublevels (see FIG. 18). We model the zero-field spectrum as arising from emission into two Gaussian ZPLs, which is apparent from the zero-field PL spectrum, and the PLE data (see FIG. 9B). Although the origin of the second ZPL requires further investigation, we note that possible explanations include: splitting of the orbitally degenerate “¹E” excited state due to the breaking of strict tetrahedral symmetry, multiple electronically distinct Cr⁴⁺ sites within the crystal, or the presence of aggregate regions in which Cr-Cr interactions modify the emission properties. To model the differential spectra we apply the Zeeman splitting to the ground-state according to Eqn. S1. All data presented in FIG. 18 are in the high-field limit (i.e., gμ_{B}B >>hD) where the Zeeman term in the Hamiltonian dominates over the orientation-dependent zero-field-splitting terms. Furthermore, the much larger inhomogeneous broadening of the ZPL (≃150 GHz) relative to the zero-field splitting (≃3.6 GHz) prevents observation of any smaller spectral shifts due to the orientation-dependent zero-field splitting terms. Taking an isotropic g=2, the spectral splitting is therefore, to a good approximation, not orientation dependent, and so no further parameters beyond the zero-field PL lineshapes are needed. FIG. 18 shows the comparison of experimental and simulated traces using this model, showing that the simulations reproduce the key features of the data.

Optical Polarization Dependence

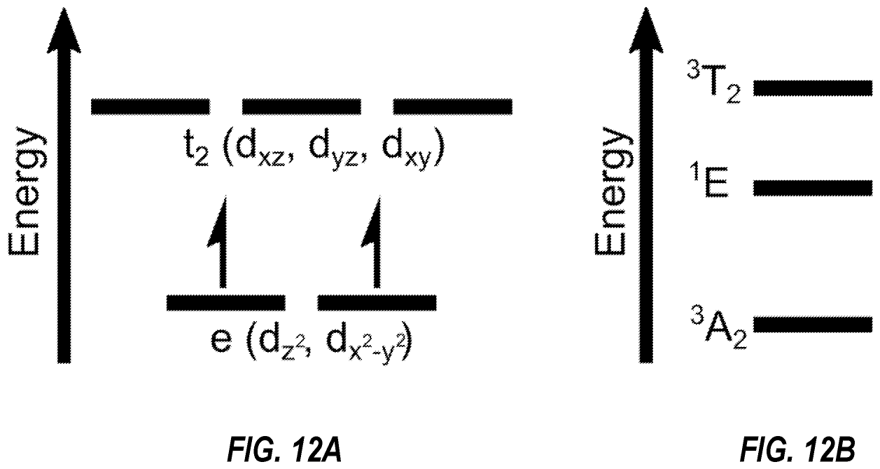

FIG. 9B shows the dependence of the PL on the laser polarization orientation, showing a maximum for polarization aligned along the long-axis of the crystal (θ=0 in FIG. 9B). Here, we outline how the observed angular dependence can be explained from the optical selection rules of the S₄ molecular symmetry associated with 1. Under ideal T_{d} symmetry, the triplet ground state is ³A₂ while the first excited singlet state is ¹E (see FIG. 12). Under the reduced S₄ symmetry of 1, the ground-state becomes ³B while the¹E singlet states splits into a ¹A and ¹B state. Under S₄ symmetry the electric dipole operator for light polarized along the S₄ symmetry axis, which we denote as z, transforms as Γ_{ed}^{(z)}=B, while the electric dipole operator for light polarized in the plane perpendicular to z transforms as Γ_{ed} ^{(x±iy)}=E. Considering the product Γₑₛ ⊗Γ_{ed} ⊗Γ_{gs}, where Γ_{gs} is the ground-state symmetry (B), Γₑₛ is the singlet excited-state symmetry (A or B), and Γ_{ed} is the symmetry of the electric-dipole operator (B or E), we find that all transitions are electric-dipole forbidden except for the transition ³B-<¹ A under z-polarization, i.e., polarization along the S₄ symmetry axis. As discussed above, the long axis of the crystal corresponds to the S₄ improper rotation symmetry axis of 1. Therefore, these electric dipole selection rules explain the observation of FIG. 9B that PL is maximized for polarization along the long axis of the crystal.

Subensemble Spin Polarization

In our experiments, the inhomogeneous optical linewidths are much greater than the zero-field splitting parameters and hence the |0 [symbol] and |±1 [symbol] spin sublevels are not directly optically resolved at low magnetic field. However, this still allows optical spin initialization and readout through resonant excitation of the narrower molecular subensembles. As outlined in the main text, a subensemble of molecules will have their |0 [symbol] ->|S₁ [symbol] transition frequency, where |S₁ [symbol] denotes the singlet excited state, matching the resonant excitation frequency, allowing them to be optically pumped into the |±1 [symbol] spin sublevels. Similarly, a separate subensemble of molecules will have their |+1 [symbol] ->|S₁) or |−1 [symbol] ->|S₁) transition frequencies matching the resonant excitation frequency, allowing them to be optically pumped into the other spin sublevels. For each subensemble, the PL will decrease as population is pumped from the probed (“bright”) spin sublevel to the unprobed (“dark”) spin sublevels—referred to as hole burning. Likewise, the PL for each subensemble will increase under spin resonance conditions (i.e. ODMR) as the “bright” and “dark” spin sublevels are mixed. Since each subensemble produces the same PL behavior, this means that subensemble spin initialization and readout can be measured, even if there is no net ensemble spin polarization.

Dynamics of Optical Spin Initialization and Readout

We consider a kinetic scheme consisting of spin-dependent optical pumping and excited-state decay, and spin-lattice relaxation. We take the incoherent limit, i.e., we neglect coherences between the different levels. Denoting the populations of the triplet spin sublevels as η₀, η₊₁, and η₋₁, and the population of the singlet excited state as ηₑ, the kinetic equations are

$${\dot{n}}_{0} = - {g}_{0} {n}_{0} + \frac{{γ}_{opt}}{3} {n}_{e} + \frac{{γ}_{{T}_{1}}}{2} [ ( {n}_{+ 1} - {n}_{0} ) + ( {n}_{- 1} - {n}_{0} ) ] \qquad ( S3 )$$

$${\dot{n}}_{+ 1} = - {g}_{1} {n}_{1} + \frac{{γ}_{opt}}{3} {n}_{e} - \frac{{γ}_{{T}_{1}}}{2} ( {n}_{+ 1} - {n}_{0} ) \qquad ( S4 )$$

$${\dot{n}}_{- 1} = - {g}_{- 1} {n}_{- 1} + \frac{{γ}_{opt}}{3} {n}_{e} - \frac{{γ}_{{T}_{1}}}{2} ( {n}_{- 1} - {n}_{0} ) \qquad ( S5 )$$

$${\dot{n}}_{e} = {g}_{0} {n}_{0} + {g}_{1} {n}_{1} + {g}_{- 1} {n}_{- 1} - {γ}_{opt} {n}_{e} \qquad ( S6 )$$

where {gᵢ} are the spin-dependent pumping rates for the triplet levels i=0, −1, +1, γₒₚₜ=Tₒₚₜ⁻¹ is the optical decay rate, and γ_{T}_{₁}=T₁⁻¹ is the spin-lattice relaxation rate. (We assume equal decay rates from the singlet state to the three spin sublevels.) In the following discussion, we take pumping from the |±1) levels to be equal i.e. g₋₁=g₊₁->g₁.

Hole-Burning Dynamics

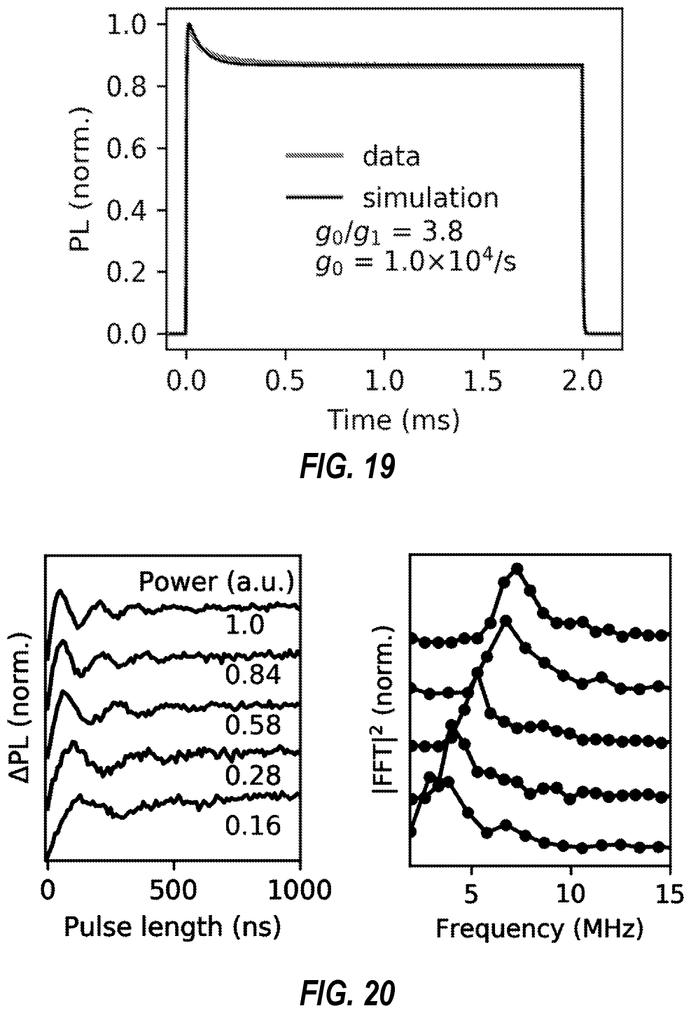

To model the hole-burning dynamics in FIG. 9D, we fit Eqns. S3-S6 to the experimental PL trace. We use the separately measured optical lifetime and spin-lattice relaxation time, leaving g₀ and g₁ as the only free parameters. The resulting fit is shown in FIG. 19, from which we extract g₀=1.0×10⁴ₛ⁻¹ and g₀/g₁=3.8. As discussed below, the observed optical contrast of 14% between the start and end of the pulse provides a lower bound on the spin polarization since the excitation is not perfectly selective i.e. g₁, g₀>0.

Estimation of the Subensemble Optical Linewidth

Using the extracted ratio g₀/g₁ outlined in the previous section, we can estimate the subensemble optical linewidth Γ_{sub} as follows. We assume that the subensemble broadening takes a Lorentzian form, so that the pumping rate for a transition at center frequency ƒ₀ is

$${g}_{s u b} = G [ \frac{1}{1 + {( \frac{f - {f}_{0}}{{Γ}_{s u b}} )}^{2}} ] , \qquad ( S7 )$$

where ƒ is the excitation frequency and G a constant.

Taking the laser frequency ƒ to match the |0 [symbol] ->|S₁ [symbol] transition frequency, the |±1 [symbol] sublevels will experience a detuning ƒ-ƒ₀≃D. (For simplicity, we take the |±1 [symbol] levels to have equal detuning since their splitting is <<D under our experimental conditions, B₀≤10 mT.) The ratio of pumping rates for the |0 [symbol] and |±1 [symbol] sublevels is then

$$\frac{{g}_{0}}{{g}_{1}} = 1 + \frac{{D}^{2}}{{Γ}_{sub}^{2}} , \qquad ( S8 )$$

$${Γ}_{sub} = \frac{D}{\sqrt{\frac{{g}_{0}}{{g}_{1}} - 1}} . \qquad ( S9 )$$

Inserting the measured D=3.6 GHz and gₒ/g₁=3.8 extracted from FIG. 19, we find

Γ_{sub}≃2 GHz. (S10)

As illustrated by the Tanabe-Sugano diagram for tetrahedral d² complexes, the spin-flip optical transition we probe is only weakly dependent on the ligand field and occurs in a primarily non-bonding orbital set, providing an attractive starting point for obtaining narrow linewidths. Determining the origin of the subensemble linewidth and how it can be reduced will be an important direction for future work. Possible origins include optical dephasing from electron-phonon coupling and spectral diffusion from environmental electronic fluctuations in the crystal due to e.g., structural reconfigurations or time-dependent variations in local photoexcitation density. These mechanisms could be investigated in future work through measuring linewidths as a function of temperature and chromium concentration, as well as through varying both the host matrix and chromium ligands. We note that the phonon-sideband subensemble linewidths in FIG. 9C will be intrinsically broader than the zero-phonon line subensemble linewidth outlined above due to the fact that the sideband linewidths are broadened by their associated phonon decay time.

Spin Polarization

Solving Eqns. S3-S6 in steady state we find that the optically induced spin polarization is given by

$$P = \frac{{n}_{1} - {n}_{0}}{{n}_{1} + {n}_{0}} = \frac{( {g}_{0} - {g}_{1} )}{( {g}_{0} + {g}_{1} ) + 3 {γ}_{{T}_{1}}} . \qquad ( S11 )$$

Taking g₀ and g₁ from the previous discussion (see FIG. 19), and the experimentally determined γ_{T}_{₁}, we find

P=28%. (S12)

Spin-Dependent Optical Contrast

The PL is given by

PL=γ_{rad}ηₑ (S13)

where γ_{rad} is the radiative part of the optical decay rate. To examine the spin dependence of the PL, we find the steady-state solutions of Eqn. S13 in the cases where (i) the |0 [symbol] and |±1 [symbol] spin sublevels are mixed only by T₁ processes and (ii) where the |0 [symbol] and |±1 [symbol] spin sublevels are fully mixed, which corresponds to a saturating microwave drive between these levels, equivalent to taking the limit γ_{T}_{₁}->∞.

The optical contrast is given by

$$C = \frac{P L ( {γ}_{{T}_{1}} \to ∞ ) - P L ( {γ}_{{T}_{1}} )}{P L ( {γ}_{{T}_{1}} )} = \frac{2 {( {g}_{0} - {g}_{1} )}^{2} {γ}_{o p t}}{3 ( 3 {γ}_{opt} + {g}_{0} + 2 {g}_{1} ) ( {g}_{1} {γ}_{{T}_{1}} + {g}_{0} ( {g}_{1} + \frac{1}{2} {γ}_{{T}_{1}} ) )} . \qquad ( S14 )$$

This highlights that optical contrast requires spin-selective excitation, i.e., C->0 for g₀=g₁. Substituting our extracted values for g₀ and g₁, along with the experimental γₒₚₜ and γ_{T}_{₁}, we find C ≃19%, close to the observed optical contrast.

Enhancing Initialization and Readout Fidelity

Further optimizing initialization and readout fidelities relies on enhancing the spin-selectivity of the optical pumping i.e. the ratio g₀/g₁ in Eqn. S8. Increasing this selectivity could be achieved through reducing the subensemble optical linewidth, increasing the zero-field splitting, or a combination of the two. For example, from Eqns. S8 and S11, we see that a reduction in the subensemble linewidth of compound 1 to Γ_{sub}=0.5 GHz, with g₀=γₒₚₜ (i.e., under optical saturation, which can be achieved by increasing the power of the laser we use), gives a spin polarization of P >90%, and a spin-selectivity in the pumping rates of g₀/g₁ >50. For comparison, we note that subensemble linewidths of less than 0.5 GHz have previously been observed in chromium complexes, and lifetime-limited linewidths of 17 MHz have been obtained for single organic molecules. Alternatively, considering the T₁, Tₒₚₜ and ≃_{sub}=2 GHz extracted for compound 1, and again setting g₀=γₒₚₜ, increasing D to 15 GHz, which is readily addressable with conventional microwave technology, results in a polarization of P >90% and spin-selectivity g₀/g₁ >50. Such an increase in zero-field splitting could be achieved by either modifying the ligands or metal center.

ODMR Simulations

Since we apply a linearly polarized microwave drive to an oriented sample, the different microwave transitions outlined in FIG. 11 have different matrix elements, and hence give rise to different ODMR intensities. To simulate the zero-field cw-ODMR spectra in FIG. 9, taking into account these microwave selection rules, we use the pepper function from the EasySpin package. The peak positions are determined by the D and E parameters, while the relative peak intensities are determined by the orientation of the zero-field splitting tensor relative to the microwave drive. To account for the line broadening, we include a Lorentzian line shape, which provides good agreement with the experimental data (see FIG. 11).

Comparison of Zero-Field Splitting Parameters from ODMR and ESR

While the sign of D and E are not resolved in our experiments, only the magnitude of D and E impact the experimental results, so we take D, E >0 throughout for clarity. However, we note that Cr⁴⁺ ions in similar ligand environments to 1-3, e.g. Cr⁴⁺ (di-tert-butylmethylsiloxide)₄, have positive D values, as does Cr⁴⁺ in 4H silicon carbide. The D and E values reported in the 77 K cw-ESR spectra (see FIG. 8G) and ≃4 K cw-ODMR spectra (see FIG. 9) differ slightly (differences in D and E are <6% and <13% respectively), which we assign to temperature dependent zero-field splitting parameters. Similar behavior has been observed and modeled in other tetrahedral Cr⁴⁺ complexes. We find that the EDFS spectra for 1, 2 and 3 (see FIG. 21), taken at 5-10 K, are well described by the D and E values obtained from cw-ODMR at ≃4 K supporting this assignment.

ODMR Linewidth and T₂*

For 1, we measure cw-ODMR linewidths (full width at half maximum) down to Δf=42 MHz. We can use this linewidth to estimate the inhomogeneous spin coherence time T₂* from T₂*=1/(πΔf). Taking Δf=42 MHz, we find T₂*≃8 ns. We note that the observed linewidths may be due to strain inhomogeneities, possibly induced by the encapsulating epoxy upon cooling the sample, as well as from hyperfine coupling to nuclear spins. Future synthetic and materials control provides opportunities to address both these mechanisms, and hence enhance T₂*.

Comparison of T₁ Times from All-Optical Measurements and Pulsed-ESR

The longer T₁ time found in the 5 K pulsed ESR measurement (see FIG. 24) relative to the all-optical measurement in FIG. 9E may arise from a slightly higher sample temperature in the optical cryostat. Possible other reasons include optical spectral diffusion, which can contribute to the optically measured T₁, but not to the ESR measurements, and the different magnetic fields used in the two measurements. The longer T₁ time measured through ESR indicates that the T₁ in optical measurements could be extended.

Prospects for Single-Molecule Detection

We estimate the steady-state photon count rate for a single molecule of compound 1 as follows. The steady-state subensemble photon count rate in our experiments is given by

r_{sub}=η_{det}η_{rad}ηₑγₒₚₜ) (S15)

where η_{det} is the total experimental photon detection efficiency, η_{rad} the radiative quantum efficiency, ηₑ the number of molecules in the excited state and γₒₚₜ=Tₒₚₜ⁻¹. The single-molecule count rate under optical saturation can be estimated by setting ηₑ˜0.5 in Eqn. S15 i.e.,

$$\begin{matrix}{r}_{s ingle} = 0.5 {η}_{det} {η}_{r a d} {γ}_{opt} \\ = 0.5 {r}_{sub} / {n}_{e} .\end{matrix}$$

We can therefore estimate the expected single-molecule count rate by dividing the experimental subensemble count rate by ηₑ, which is given by

ηₑ=η_{probed}ƒₑ, (S16)

where η_{probed} is the number of chromium molecules probed and ƒₑ is the fraction of these molecules in their excited state. The number of chromium molecules η_{conf} in the confocal volume V_{conf}≃1.4 μm³ of the excitation spot is given by

$${n}_{conf} = {c}_{C r} \frac{{V}_{conf}}{( {V}_{cell} / Z )} , \qquad ( S17 )$$

where c_{Cr}=0.75% is the Cr:Sn ratio (Materials and Methods), V_{Cell}=1.12 nm³ is the unit cell volume and Z=2 the number of molecules per unit cell (see FIG. 27). Under resonant excitation, we probe a fraction Γ_{sub}/Γᵢₙₕₒₘ of these molecules, where Γ_{sub}≃2 GHz and Γᵢₙₕₒₘ≃150 GHz are the subensemble and inhomogeneous optical linewidths respectively, giving

$${n}_{probed} = {c}_{C r} \frac{{V}_{conf}}{( {V}_{cell} / Z )} ( \frac{{Γ}_{sub}}{{Γ}_{inhom}} ) \qquad ( S18 )$$

Based on the steady-state rate equations (i.e., Eqns. S3-S6), and using the measured T₁, Tₒₚₜ and extracted pumping rates (see FIG. 19) we estimate a fraction ƒₑ≃1% of the molecules are in the excited state for an ensemble count rate of r_{sub} ≃1 Mcts/s. We therefore find

$$\begin{matrix}{r}_{s ingle} = 0.5 {r}_{sub} / {n}_{e} \\ = \frac{{r}_{e n s}}{2 {c}_{Cr} \frac{{V}_{conf}}{( {V}_{cell} / Z )} ( \frac{{Γ}_{sub}}{{Γ}_{inhom}} ) {f}_{e}} \\ ≃ 300 cts / s .\end{matrix}$$

This count rate is above the dark-count rate of our detector of ≃5 cts/s, suggesting that single-molecule detection could be feasible with our current confocal microscope, provided background scatter can be suppressed, for example, through temporal gating. For an experimental comparison to these estimates, we note that single-molecule phosphorescence has been detected using a confocal microscope with count rates of 2000 cts/s in a system with a 36 μs phosphorescence lifetime, and that single V⁴⁺ ions have been detected with a count rate of ˜100 cts/s. Enhancements in collection efficiency, and a reduction in the radiative lifetime through Purcell enhancement will be promising directions to enhance single-molecule count rates. We estimate our current detection efficiency as/met 1% from the product of the collection efficiency of the objective (≃20%), transmission through optical components (≃40%), coupling efficiency into single-mode fiber (≃25%), detector efficiency (≃80%), and the fraction of photons in the phonon sideband (≃70%). Near-ideal collection efficiencies have been achieved for single molecules coupled to a dielectric antenna, and more modest enhancements of ˜5 times could be readily obtained with an external solid-immersion lens, indicating pathways for future optimization. Integration with photonic resonators further offers opportunities for emission enhancement and appears particularly attractive given the portability of molecular qubits. For example, the compounds in the main text could be evanescently coupled to a photonic resonator to reduce their optical lifetimes through the Purcell effect, hence enhancing their emission rates. We note that such an approach has been successfully applied to detect single erbium ions in yttrium orthosilicate despite starting from a bulk optical lifetime of 11 ms, which is much longer than we observe.

Estimate of the Radiative Quantum Efficiency

From Eqn. S15 we have

$$\begin{matrix}{η}_{r a d} = \frac{{r}_{sub}}{{η}_{det} {n}_{e} {γ}_{opt}} \\ = \frac{{r}_{sub}}{{η}_{det} {c}_{C r} \frac{{V}_{conf}}{( {V}_{cell} / Z )} ( \frac{{Γ}_{sub}}{{Γ}_{inhom}} ) {f}_{e} {γ}_{o p t}}\end{matrix} .$$

Using the parameters outlined in the previous section for compound 1, we estimate

η_{rad}≃10% (S19)

Qubit Figure of Merit

One figure of merit Q_{M} to characterize a qubit is the number of spin-flip operations that can be performed within the coherence time i.e., Q_{M}=ΩT₂/π where Ω is the microwave Rabi frequency. Taking our experimental Ω=2π·7.3 MHz (see FIG. 20) and T₂=640 ns (see FIG. 10F) we find Q_{M}≃9. We expect that future improvements in T₂ through for example, deuteration and the use of clock transitions, as well as increasing our experimental microwave drive strength should significantly enhance the Q_{M} obtainable in optically addressable molecular spin qubits.

Methods for Off-Resonant Initialization and Readout

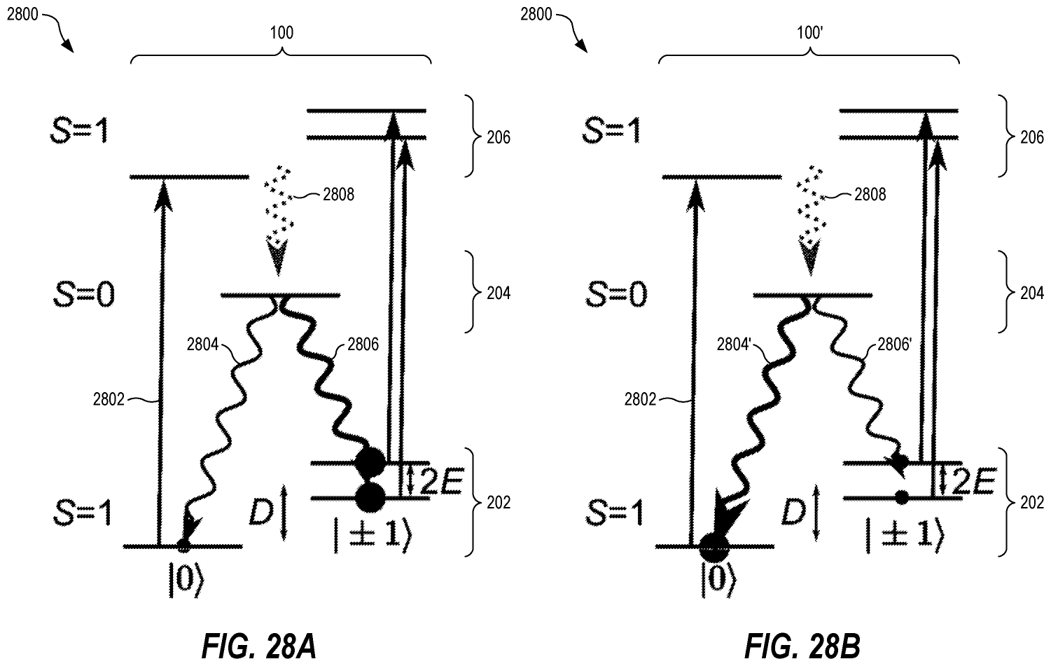

FIG. 28A illustrates a method 2800 for off-resonant optical pumping of the coordination complex 100. The method 2800 is based on spin-selective emission and may be used, for example, to initialize the coordination complex 100 (i.e., optically pump an ensemble of the coordination complex 100 such the ensemble has a non-zero ground-state spin polarization). Here, “off-resonant” means that the coordination complex 100 is optically excited to a second excited state 206 whose energy is higher than that of the excited state 204. The second excited state 206 has a total spin S that is the same as that of the ground state 202 and different from that of the excited state 206. In the example of FIG. 28A, the ground state 202 and second excited state 206 have total spin S=1 while the excited state 204 has total spin S=0. However, the states 202, 204, and 206 may have other values of total spin S without departing from the scope hereof.

In the method 2800, an optical field 2802 excites the coordination complex 100 from the ground state 202 to the second excited state 206. In FIG. 28A, the optical field 2802 is shown exciting all three Δm=0 transitions between the magnetic sublevels of the ground state 202 and the magnetic sublevels of the second excited state 206. Those trained in the art will recognize that changing the polarization of the optical field 2802 (e.g., from linear to circular) and the direction with which the optical field 2802 illuminates the coordination complex, Δm=±1 transitions may be alternatively or additionally excited.

From the second excited 206, the coordination complex 100 rapidly decays to the excited state 204 via intersystem crossing 2808. The coordination complex 100 then undergoes spin-selective emission from the excited state 204 to one of the three magnetic sublevels |m=−1 [symbol] , |m=0 [symbol] , and |m=+1 [symbol] of the ground state 202. When the coordination complex 100 decays to the |m=0 [symbol] ground-state sublevel, phosphorescence 2804 is emitted. When the coordination complex 100 decays to either of the |m=±1 [symbol] ground-state sublevels, phosphorescence 2806 is emitted. Here, “spin-selective emission” means that the coordination complex 100 spontaneously decays from the excited state 204 to the ground-state magnetic sublevels with different decay rates. In the example of FIG. 28A, the coordination complex 100 decays to the |m=±1 [symbol] ground-state sublevels at higher rates than to the |m=0 [symbol] ground-state sublevel. To indicate this difference in decay rates in FIG. 28A, the phosphorescence 2806 is represented by a thicker line than the phosphorescence 2804.

After several optical pumping cycles, the population will preferentially accumulate in some (i.e., one or two) of the ground-state magnetic sublevels, thereby producing a non-zero ground-state spin polarization. In the example of FIG. 28A, the population accumulates in the |m=±1 [symbol] ground-state sublevels. Selective decay typically arises from spin-orbit effects of the coordination complex 100. Alternatively or additionally, the coordination complex 100 may be coupled to an optical cavity that preferentially enhances spontaneous emission into one or more of the ground-state sublevels while suppressing emission into the other ground-state sublevels.

FIG. 28B shows how the method 2800 may be used with a coordination complex 100′ that is similar to the coordination complex 100 except that it has different spin-orbit coupling, and therefore its spin-selective emission is different from that of the coordination complex 100. In the case of FIG. 28B, the coordination complex 100′ has a decay rate to the ground-state sublevel |m=0 [symbol] that is greater than the decay rates to the ground-state sublevels |m=±1 [symbol] . To indicate this difference in decay rates in FIG. 28B, phosphorescence 2804′ is represented by a thicker line than phosphorescence 2806′. Therefore, in the example of FIG. 28B, the population accumulates in the |m=0 [symbol] ground-state sublevels.

The examples of FIGS. 28A and 28B show how the coordination complexes 100 and 100′ may be chemically engineered to have different spin-selective emission, giving rise to different amounts and types of ground-state spin polarization (i.e., parallel or perpendicular to the |m=0) ground-state sublevel). The spin-orbit interaction may be engineered, for example, via the number of ligands 104, type of ligands 104, and type of metal-atom center 102.

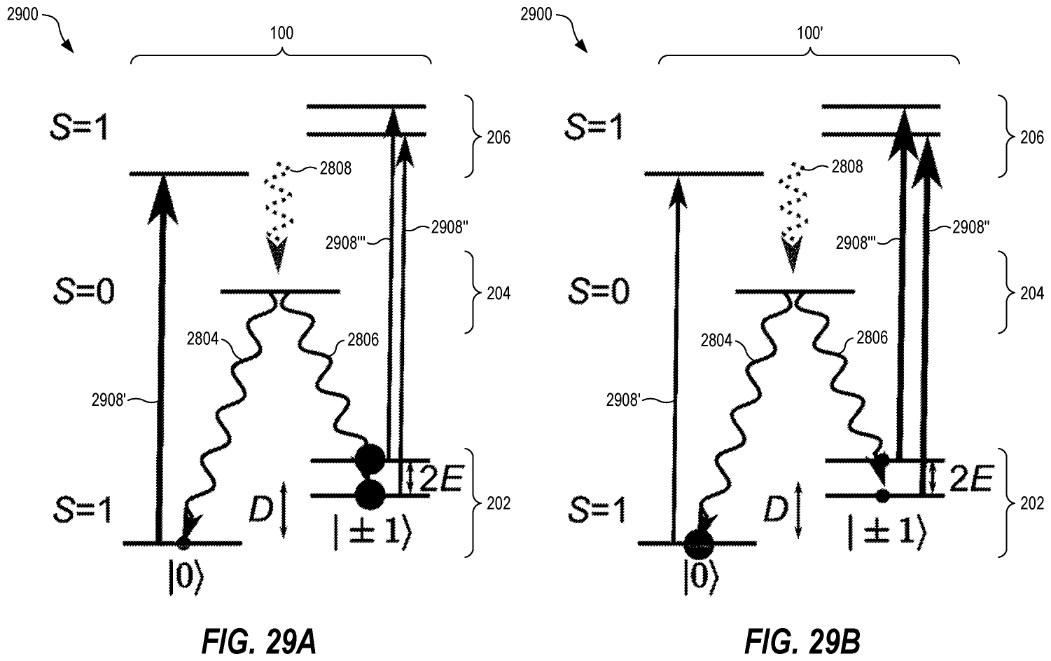

FIG. 29A illustrates a method 2900 for off-resonant optical pumping of the coordination complex 100 that is based on spin-selective excitation. The method 2900 is similar to the method 2800 of FIGS. 28A and 28B in that an optical field excites the coordination complex 100 from the ground state 202 to the second excited state 206. Specifically, the optical field excites the |m=0 [symbol] ground-state sublevel to the |m=0 [symbol] sublevel of the second excited state 206 with a first pumping rate 2908′, the |m=−1 [symbol] ground-state sublevel to the |m=−1 [symbol] sublevel of the second excited state 206 with a second pumping rate 2908″, and the |m=+1 [symbol] ground-state sublevel to the |m=+1 [symbol] sublevel of the second excited state 206 with a third pumping rate 2908″. The term “spin-selective excitation” means that the coordination complex 100 has a structure such that the pumping rates 2908′, 2908″, and 2908″′ are different. For example, in FIG. 29A the pumping rate 2908′ is greater than the pumping rates 2908″ and 2908″. To indicate these differences in pumping rates in FIG. 29A, the pumping rates 2908′, 2908″, and 2908″′ are shown as lines of different thickness. After several optical pumping cycles, the population will preferentially accumulate in some (i.e., one or two) of the ground-state magnetic sublevels, thereby producing a non-zero ground-state spin polarization. In the example of FIG. 29A, the population accumulates in the |m=±1 [symbol] ground-state sublevels.

FIG. 29B shows how the method 2900 may be used with the coordination complex 100′. Due to the change in spin-orbit coupling (as compared to the coordination complex 100), the pumping rate 2908′ is less than the pumping rates 2908″ and 2908″′, as indicated by the thicknesses of the lines representing the pumping rates 2908′, 2908″, and 2908″′. In this case, the population accumulates in the |m=0 [symbol] ground-state sublevels. Therefore, the examples of FIGS. 29A and 29B show how coordination complexes may be engineered to have different spin-orbit coupling, and therefore spin-selective excitation that results in different amounts and types of ground-state spin polarization. The coordination complexes 100 and 100′ may be engineered to have both spin-selective excitation and spin-selective emission, in which case the methods 2800 and 2900 may be performed simultaneously.

In some embodiments of the method 2900, the polarization of the optical field 2802 may be selected to implement polarization selection rules that address specific orbital excited-state manifolds. The three magnetic sublevels of the second excited state 206 shown in FIGS. 29A and 29B represent only one orbital excited-state manifold of the coordination complex 100. Although not shown in FIGS. 29A and 29B, it should be understood that there are other orbital excited-state manifolds. The coordination complex 100 may be engineered such that these other orbital-state manifold are degenerate, or nearly degenerate, with the second excited state 206. In this case, the polarization of the optical field may be varied to excite some of these other orbital excited states. These other orbital excited states may exhibit selective excitation, selective decay, or both. Accordingly, the polarization of optical field may be thought of as an experimental “knob” that can be adjusted to vary the amount of ground-state spin polarization.

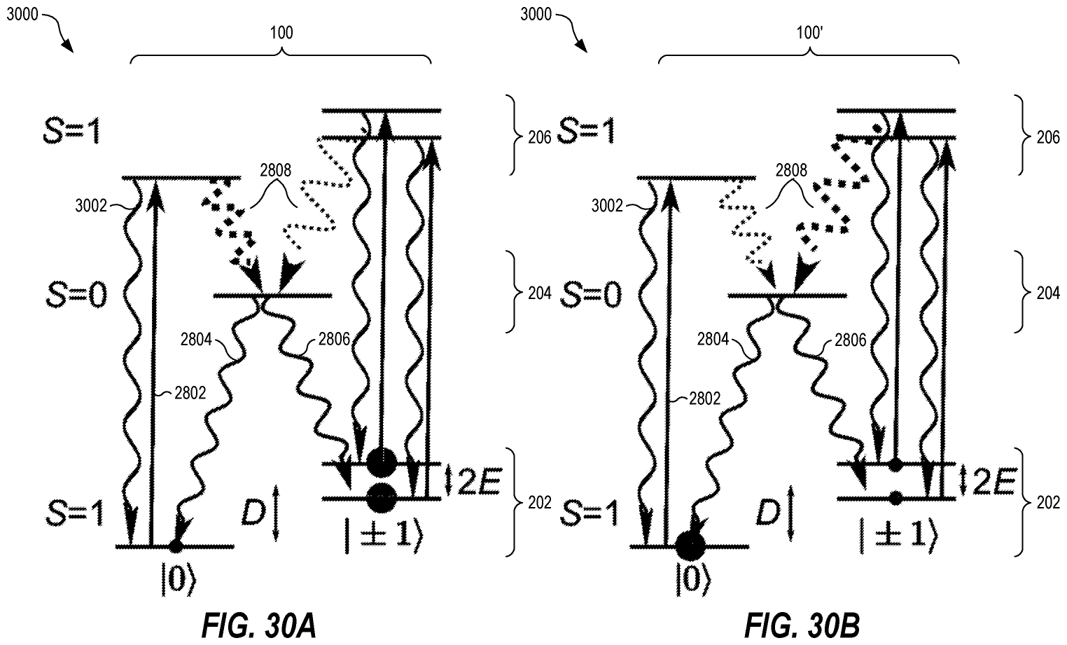

FIG. 30A illustrates a method 3000 for off-resonant optical pumping of the coordination complex 100 that is based on an intersystem crossing. The method 3000 is similar to the methods 2800 and 2900 in that an optical field 2802 excites all of the ground-state magnetic sublevels to the second excited state 206. The coordination complex 100 may have high decay rates from the second excited state 206 to the ground state 202, as indicated in FIG. 30A. These decays are spin-preserving (i.e., the total spin S does not change) and therefore the corresponding emission is fluorescence 3002. Alternatively, this decay could occur via a radiationless transition through internal conversion. In addition, the population may decay from the second excited state 206 to the excited state 204 through the intersystem crossing 2808. These decays are spin-changing (i.e., the total spin S does change) and mediated through spin-orbit coupling. The decay rates to the excited state 204 may be different for the magnetic sublevels of the second excited state 206. Like the method 2800, these differences in decay rates cause the population to accumulate in some of the ground-state magnetic sublevels, thereby resulting in a ground-state spin polarization. In the example of FIG. 30A, the decay rates to the excited state 204 are such that the population accumulates in the |m=±1 [symbol] ground-state sublevels.

FIG. 30B shows how the method 3000 may be used with the coordination complex 100′. Due to the change in spin-orbit coupling (as compared to the coordination complex 100), decay rates from the second excited state 206 to the excited state 204 have changed. In this case, the population accumulates in the |m=0 [symbol] ground-state sublevel. Therefore, FIGS. 30A and 30B show how the coordination complexes 100 and 100′ may be engineered to have different intersystem crossing decay rates, thereby resulting in different amounts and types of ground-state spin polarization. Furthermore, the coordination complexes 100 and 100′ may be engineered to have any combination of intersystem crossing decay rates, spin-selective excitation, and spin-selective emission, in which case two or more of the methods 2800, 2900, and 3000 may be performed simultaneously.

Any of the off-resonant optical pumping methods 2800, 2900, and 3000 may be combined with any of the spin manipulation techniques described above. Furthermore, the method 2900 (either alone, or in combination with one or both of the methods 2800 and 3000) may also be used for readout by optically detecting the emitted phosphorescence and/or fluorescence.

It is possible to increase the temperature range over which the present coordination complexes can operate by using spin-selective excitation to overcome spectral broadening. Furthermore, it may be possible to increase the spin relaxation time T₁ for a given temperature by modifying phonon modes through molecular design.

Combination of Features

Features described above as well as those claimed below may be combined in various ways without departing from the scope hereof. The following examples illustrate possible, non-limiting combinations of features and embodiments described above. It should be clear that other changes and modifications may be made to the present embodiments without departing from the spirit and scope of this invention:

(A1) A method for spin polarizing a molecular-spin qubit includes exciting a coordination complex via an optical transition between a first sublevel of a ground state and an excited state such that the coordination complex decays from the excited state to a second sublevel of the ground state. The first and second sublevels are non-degenerate.

(A2) In the method denoted (A1), a spin-lattice relaxation time of the ground state may be greater than a lifetime of the excited state.

(A3) In either one of the methods denoted (A1) and (A2), the optical transition may be a zero-phonon line.

(A4) In any one of the methods denoted (A1) to (A3), the ground state may be a spin-triplet state with three magnetic sublevels having magnetic quantum numbers m=−1, m=0, and m=+1. The first and second sublevels may be selected from the group consisting of the three magnetic sublevels.

(A5) In any one of the methods denoted (A1) to (A4), the coordination complex may include a metal ion with a d² electronic configuration.

(A6) In the method denoted (A5), the metal ion is a Group 6 metal with an oxidation state of +4.

(A7) In the method denoted (A6), the metal ion is a Cr⁴⁺ ion.

(A8) In any one of the methods denoted (A1) to (A7), the coordination complex may include four strong-field ligands bonded to a metal-atom center. The four strong-field ligands may form a pseudo-tetrahedral environment within which the metal-atom center is located.

(A9) In any one of the methods denoted (A1) to (A8), the optical transition may lie within the infrared region of the electromagnetic spectrum.

(A10) In any one of the methods denoted (A1) to (A9), the method may further include detecting photoluminescence emitted by the coordination complex during said exciting, and stopping said exciting when a level of the detected photoluminescence falls below a threshold.

(A11) In any one of the methods denoted (A1) to (A10), an energy spacing between a first and second sublevels may lie within the microwave or millimeter-wave regions of the electromagnetic spectrum.

(A12) In any one of the methods denoted (A1) to (A11), said exciting may include exciting the coordination complex with an optical field. Furthermore, the method may further include selecting a polarization of the optical field to enhance optical pumping of the coordination complex into the second sublevel.

(A13) In any one of the methods denoted (A1) to (A12), the coordination complex being represented by formula (II):

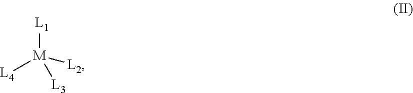

where M is V³⁺, Cr⁴⁺, Mo⁴⁺, or W⁴⁺. Each of L₁, L₂ L₃, and L₄ represents a monodentate ligand independently selected from the group consisting of cyano, nitro, amido, aryl, deuterated aryl, heteroaryl, and deuterated heteroaryl. Said aryl, deuterated aryl, heteroaryl, and deuterated heteroaryl are optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl.

(B1) A method for manipulating a molecular-spin qubit includes driving, with an electromagnetic field, a spin transition of a spin-polarized coordination complex to coherently transfer the coordination complex between two sublevels of a ground state. The spin transition has a non-zero energy.

(B2) In the method denoted (B1), said driving the spin transition may include resonantly driving the spin transition with microwaves or millimeter-waves.

(B3) In either one of the methods denoted (B1) and (B2), said driving the spin transition may include applying a π/2 pulse to prepare the coordination complex in an equal superposition of the two sublevels.

(B4) In any one of the methods denoted (B1) to (B3), the ground state is a spin-triplet state with three magnetic sublevels having magnetic quantum numbers m=−1, m=0, and m=+1. The two sublevels may be selected from the group consisting of the three magnetic sublevels.

(B5) In any one of the methods denoted (B1) to (B4), the method further includes selecting a polarization of the electromagnetic field to reduce coupling to sublevels other than the two sublevels.

(C1) A method for determining spin of a molecular-spin qubit includes exciting a coordination complex via an optical transition between a first sublevel of a plurality of non-degenerate sublevels of a ground state and an excited state such that the coordination complex decays from the excited state to any of the plurality of non-degenerate sublevels. The method also includes detecting photoluminescence emitted by the coordination complex during said exciting, and determining, based on a level of the detected photoluminescence, a population of the coordination complex prior to said exciting.

(C2) In the method denoted (C1), the optical transition may lie within the infrared region of the electromagnetic spectrum.

(C3) In either one of the methods denoted (C1) and (C2), the optical transition may be a zero-phonon line.

(C4) In any one of the methods denoted (C1) to (C3), a spin-lattice relaxation time of the ground state may be greater than a lifetime of the excited state.

(C5) In any one of the methods denoted (C1) to (C4), the ground state may be a spin-triplet state such that the plurality of non-degenerate sublevels consists of three magnetic sublevels with magnetic quantum numbers m=−1, m=0, and m=+1.

(D1) A molecular-spin qubit includes a plurality of strong-field ligands bound to a metal-atom center such that the metal-atom center has a ground state with non-zero spin and an excited state. An optical transition between the ground state and the excited state lies in the optical or infrared region of the electromagnetic spectrum, and a spin transition between first and second sublevels of the ground state lies in the microwave or millimeter-wave region of the electromagnetic spectrum.

(D2) In the molecular-spin qubit denoted (D1), the ground state may be a spin-triplet state with three magnetic sublevels having magnetic quantum numbers m=−1, m=0, and m=+1. The first and second sublevels may be selected from the group consisting of the three magnetic sublevels.

(D3) In either one of the molecular-spin qubits denoted (D1) and (D2), a spin-lattice relaxation time of the ground state may be greater than a lifetime of the excited state.

(D4) In any one of the molecular-spin qubits denoted (D1) to (D3), the optical transition may be a zero-phonon line.

(D5) In any one of the molecular-spin qubits denoted (D1) to (D4), the metal-atom center may be a metal ion with a d² electronic configuration.

(D6) In the molecular-spin qubit denoted (D5), the metal ion may be a Cr⁴⁺ ion.

(D7) In any one of the molecular-spin qubits denoted (D1) to (D6), the plurality of strong-field ligands may form a pseudo-tetrahedral environment within which the metal-atom center is located.

(D8) In any one of the molecular-spin qubits denoted (D1) to (D7), the metal-atom center and the plurality of strong-field ligands being represented by formula (II):

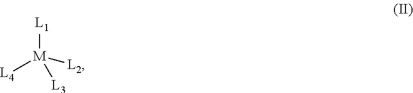

where M is a V³⁺, Cr⁴⁺, Mo⁴⁺, or W⁴⁺ and each of L₁, L₂ L₃, and L₄ represents a monodentate ligand independently selected from the group consisting of cyano, nitro, amido, aryl, deuterated aryl, heteroaryl, and deuterated heteroaryl. Said aryl, deuterated aryl, heteroaryl, and deuterated heteroaryl may be optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl.

(E1) A metal-ligand complex has the structure of formula (I):

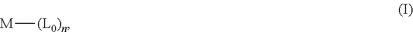

wherein M is selected from the group consisting of Ti²⁺, V³⁺, Cr⁴⁺, Mo⁴⁺, W⁴⁺, Mn⁴⁺, Fe²⁺, Co¹⁺, Ni²⁺, and U⁴⁺. Furthermore, L₀ for each occurrence represents a monodentate ligand independently selected from the group consisting of cyano, nitro, amido, aryl, deuterated aryl, heteroaryl, and deuterated heteroaryl, wherein said aryl, deuterated aryl, heteroaryl, and deuterated heteroaryl are optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl. Furthermore, n is 4, 5, or 6.

(E2) In the metal-ligand complex denoted (E1), n is 4 or 5 when M is V³⁺, n is 4 when M is Cr⁴⁺, n is 4 when M is Mo⁴⁺, n is 4 when M is W⁴⁺, and n is 6 when M is Ni²⁺.

(F1) A metal-ligand complex has the structure of formula (II):

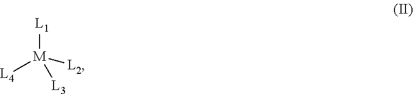

where M is V³⁺, Cr⁴⁺, Mo⁴⁺, or W⁴⁺ and each of L₁, L₂ L₃, and L₄ represents a monodentate ligand independently selected from the group consisting of cyano, nitro, amido, aryl, deuterated aryl, heteroaryl, and deuterated heteroaryl. Said aryl, deuterated aryl, heteroaryl, and deuterated heteroaryl may be optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl.

(F2) In the metal-ligand complex denoted (F1), M may be Cr⁴⁺.

(F3) In either one of the metal-ligand complexes denoted (F1) and (F2), L₁, L₂, L₃, and L₄ may be identical.

(F4) In any one of the metal-ligand complexes denoted (F1) to (F3), L₁, L₂, L₃, and L₄ may be selected from the group consisting of aryl, deuterated aryl, heteroaryl, and deuterated heteroaryl. Said aryl, deuterated aryl, heteroaryl, and deuterated heteroaryl may be optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, deuterated C₁₋₆ haloalkyl.

(F5) In any one of the metal-ligand complexes denoted (F1) to (F4), the metal-ligand complex has a structure according to formula (III):

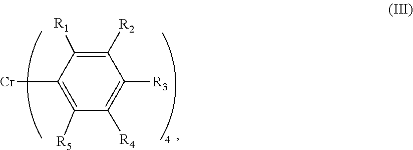

where (i) R₁ is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, (ii) R₂ is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, (iii) R₃ is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, (iv) R₄ is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, and (v) R₅, is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl.

(G1) A crystal includes a metal-ligand complex of formula (III):

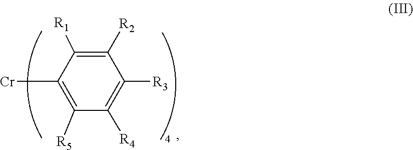

and a metal-ligand complex of formula (IV):

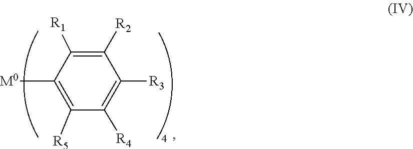

where M⁰ is selected from the group consisting of Sn⁴⁺, Ge⁴⁺, Si⁴⁺, and Ti⁴⁺. Furthermore, (i) R₁, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, (ii) R₂, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, (iii) R₃, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, (iv) R₄, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl, and (v) R₅, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl.

(G2) In the crystal denoted (G1), the ratio of chromium to M⁰ may be less than or equal to 10%.

(G3) In either one of the crystals denoted (G1) and (G2), the ratio of chromium to M⁰ may be less than or equal to 1%.

(G4) In any one of the crystals denoted (G1) to (G3), M⁰ may be tin.

(H1) A method for sensing an external magnetic field includes polarizing a molecular-spin qubit and measuring a shift in at least one resonant frequency of a ground-state spin transition of the molecular-spin qubit. The method also includes determining a magnitude of the external magnetic field based on the shift.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

1-23. (canceled)

24. A molecular-spin qubit comprising:
a plurality of strong-field ligands bound to a metal-atom center such that the metal-atom center has a ground state with non-zero spin and an excited state;
wherein an optical transition between the ground state and the excited state lies in the optical or infrared regions of the electromagnetic spectrum, and a spin transition between first and second sublevels of the ground state lies in the microwave or millimeter-wave region of the electromagnetic spectrum.

25. The molecular-spin qubit of claim 24, wherein:
the ground state is a spin-triplet state with three magnetic sublevels having magnetic quantum numbers m=−1, m=0, and m=+1; and
the first and second sublevels are selected from the group consisting of the three magnetic sublevels.

26. The molecular-spin qubit of claim 24, wherein a spin-lattice relaxation time of the ground state is greater than a lifetime of the excited state.

27. The molecular-spin qubit of claim 24, wherein the optical transition is a zero-phonon line.

28. The molecular-spin qubit of claim 24, wherein the metal-atom center is a metal ion with a d² electronic configuration.

29. The molecular-spin qubit of claim 28, wherein the metal ion is a Cr⁴⁺ ion.

30. The molecular-spin qubit of claim 24, wherein the plurality of strong-field ligands forms a pseudo-tetrahedral environment within which the metal-atom center is located.

31. The molecular-spin qubit of claim 24, wherein the metal-atom center and the plurality of strong-field ligands are represented by formula (II): 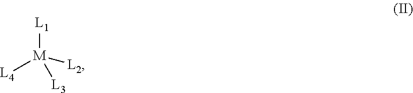
wherein:
M is V³⁺, Cr⁴⁺, Mo⁴⁺, or W⁴⁺; and
each of L₁, L₂ L₃, and L₄ represents a monodentate ligand independently selected from the group consisting of cyano, nitro, amido, aryl, deuterated aryl, heteroaryl, and
deuterated heteroaryl, wherein said aryl, deuterated aryl, heteroaryl, and
deuterated heteroaryl are optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl.

32. A metal-ligand complex of formula (I): 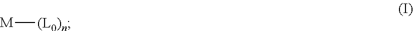
wherein:
M is selected from the group consisting of Ti²⁺, V³⁺, Cr⁴⁺, Mo⁴⁺, W⁴⁺, Mn⁴⁺, Fe²⁺, Co¹⁺, and Ni²⁺;
L₀ for each occurrence represents a monodentate ligand independently selected from the group consisting of cyano, nitro, amido, aryl, deuterated aryl, heteroaryl, and deuterated heteroaryl, wherein said aryl, deuterated aryl, heteroaryl, and deuterated heteroaryl are optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl; and
n is 4, 5, or 6.

33. The metal-ligand complex of claim 32, wherein:
when M is V³⁺, n is 4 or 5;
when M is Cr⁴⁺, n is 4;
when M is Mo⁴⁺, n is 4;
when M is W⁴⁺, n is 4; and
when M is Ni²⁺, n is 6.

34. The metal-ligand complex of claim 32, having a structure according to formula (II): 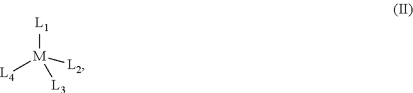
wherein:
M is V³⁺, Cr⁴⁺, Mo⁴⁺, or W⁴⁺; and
each of L₁, L₂ L₃, and L₄ represents a monodentate ligand independently selected from the group consisting of cyano, nitro, amido, aryl, deuterated aryl, heteroaryl, and deuterated heteroaryl, wherein said aryl, deuterated aryl, heteroaryl, and deuterated heteroaryl are optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, and deuterated C₁₋₆ haloalkyl.

35. The metal-ligand complex of claim 34, wherein M is Cr⁴⁺.

36. The metal-ligand complex of claim 34, wherein L₁, L₂, L₃, and L₄ are identical.

37. The metal-ligand complex of claim 34, wherein L₁, L₂, L₃, and L₄ are selected from the group consisting of aryl, deuterated aryl, heteroaryl, and deuterated heteroaryl, wherein said aryl, deuterated aryl, heteroaryl, and deuterated heteroaryl are optionally substituted by one, two, or three substituents independently selected from the group consisting of C₁₋₆ alkyl, deuterated C₁₋₆ alkyl, halo, C₁₋₆ alkoxy, deuterated C₁₋₆ alkoxy, C₁₋₆ haloalkyl, deuterated C₁₋₆ haloalkyl.

38. The metal-ligand complex of claim 34, having a structure according to formula (III): 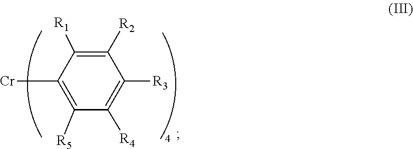
wherein:
R₁ is hydrogen, deuterium, C₁₋₆ alkyl, deuterated C₁₋₆ alkyl, halo, C₁₋₆ C₁₋₆ alkoxy, C₁₋₆ haloalkyl, or deuterated C₁₋₆ haloalkyl;
R₂ is hydrogen, deuterium, C₁₋₆ alkyl, deuterated C₁₋₆ alkyl, halo, C₁₋₆ C₁₋₆ alkoxy, C₁₋₆ haloalkyl, or deuterated C₁₋₆ haloalkyl;
R₃ is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl;
R₄ is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl; and
R₅, is hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl.

39. A crystal comprising:
a metal-ligand complex of formula (III): 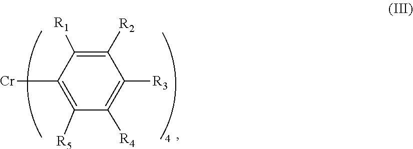
and
a metal-ligand complex of formula (IV): 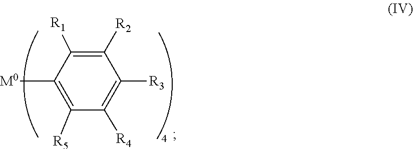
wherein:
M⁰ is selected from the group consisting of Sn⁴⁺, Ge⁴⁺, Si⁴⁺, and Ti⁴⁺;
R₁, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl;
R₂, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl;
R₃, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl;
R₄, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl;
R₅, for each is occurrence, is uniformly selected from the group consisting of hydrogen, deuterium, C₁₋₆ alkyl, deuterated C₁₋₆ alkyl, halo, C₁₋₆ alkoxy, deuterated C₁₋₆ alkoxy, C₁₋₆ haloalkyl, or deuterated C₁₋₆ haloalkyl.

40. The crystal of claim 39, wherein the ratio of chromium to M⁰ is less than or equal to 10%.

41. The crystal of claim 39, wherein the ratio of chromium to M⁰ is less than or equal to 1%.

42. The crystal of claim 39, wherein M⁰ is tin.

43. (canceled)

44. The molecular spin qubit of claim 31, wherein L₁, L₂, L₃, and L₄ are identical.
